(19) United States
(12) Patent Application Publication
(10) Pub. No.: US 2025/0142998 A1
(43) Pub. Date: May 1, 2025

(54) IMAGE SENSOR

(71) Applicant: Samsung Electronics Co., Ltd., Suwon-si (KR)

(72) Inventors: Taemin KIM, Suwon-si (KR); Jungsan KIM, Suwon-si (KR); Yongsoon PARK, Suwon-si (KR); Seungho LEE, Suwon-si (KR)

(73) Assignee: Samsung Electronics Co., Ltd., Suwon-si (KR)

(21) Appl. No.: 18/769,794

(22) Filed: Jul. 11, 2024

(30) Foreign Application Priority Data
Oct. 27, 2023 (KR) 10-2023-0145954

(51) Int. Cl. H01L 27/146

(52) U.S. Cl. CPC H10F 39/807; H10F 39/011; H10F 39/182; H10F 39/806

(57) ABSTRACT

An image sensor includes a substrate including adjacent first and second pixel regions; a photoelectric converter at the substrate; and a pixel isolation portion separating the first and second pixel regions based on penetrating at least a part of the substrate between the first and second pixel regions. The pixel isolation portion includes first and second insulation portions respectively adjacent to the first and second pixel regions, and a conductive layer and an inner layer between the first and second insulation portions and including different materials. The pixel isolation portion includes a first portion including a portion where the conductive layer occupies a space between the first and second insulation portions in an intersection direction that intersects an extension direction of the pixel isolation portion, and a second portion including the conductive layer and the inner layer between the first and second insulation portions in the intersection direction.

### CROSS-REFERENCE TO RELATED APPLICATION

This application claims priority to and the benefit of Korean Patent Application No. 10-2023-0145954 filed in the Korean Intellectual Property Office on Oct. 27, 2023, the entire contents of which are incorporated herein by reference.

### BACKGROUND

### (a) Field

The present inventive concepts relate to image sensors, and more particularly, to image sensors with an improved structure.

### (b) Description of the Related Art

An image sensor is a semiconductor device that converts optical images into electric signals. The image sensors may be classified into charge coupled device (CCD)-typed image sensors based on silicon semiconductors and complementary metal oxide semiconductor (CMOS)-typed image sensors (CIS).

Among these, the CMOS-typed image sensor may have a simple driving method and be integrated with a signal processing circuit as a single chip to allow for a down-sizing, and may have a low power consumption to be applied to products with a limited battery capacity. With the advancement of the electron industry, various studies are continuing to improve the performance of the CMOS-typed image sensors.

### SUMMARY

Some example embodiments seek to provide an image sensor with enhanced performance.

An image sensor according to some example embodiments may include a substrate including a plurality of pixel regions including a first pixel region and a second pixel region adjacent to each other; a photoelectric converter on the substrate; and a pixel isolation portion that separates the first pixel region and the second pixel region based on penetrating at least a part of the substrate between the first pixel region and the second pixel region. The pixel isolation portion may include first and second insulation portions respectively adjacent to the first and second pixel region, and a conductive layer and an inner layer between the first and second insulation portions. The conductive layer and the inner layer may include different materials. The pixel isolation portion may include a first portion including a portion where the conductive layer occupies a space defined between the first and second insulation portions in an intersection direction that intersects an extension direction of the pixel isolation portion, and a second portion including the conductive layer and the inner layer between the first and second insulation portions in the intersection direction.

An image sensor according to some example embodiments may include a substrate including a plurality of pixel regions; a photoelectric converter at the substrate; a light scattering pattern at a position adjacent to one surface of the substrate; and a pixel isolation portion that separates the plurality of pixel regions based on penetrating at least a part of the substrate between the plurality of pixel regions. The pixel isolation portion may include a first portion and a second portion having a width greater than a width of the first portion in an intersection direction that intersects an extension direction of the pixel isolation portion. The second portion may include an insulation layer adjacent to the plurality of pixel regions, a conductive layer on the insulation layer, and an inner layer at an inside of the conductive layer and having a refractive index less than a refractive index of the conductive layer.

An image sensor according to some example embodiments may include a substrate including a plurality of pixel regions including a first pixel region and a second pixel region adjacent to each other; a photoelectric converter at the substrate; and a pixel isolation portion that separates the first pixel region and the second pixel region based on penetrating at least a part of the substrate between the first pixel region and the second pixel region. The pixel isolation portion may include a first portion including first and second insulation portions respectively adjacent to the first and second pixel regions and a conductive layer that occupies a space defined between the first and second insulation portions in an intersection direction that intersects an extension direction of the pixel isolation portion, and a second portion having a width greater than a width of the first portion and a stacking structure different from a stacking structure of the first portion to have an electrical insulation structure.

According to some example embodiments, an amount of light absorbed in the conductive layer may be reduced by reducing a thickness of the conductive layer, which may absorb a relatively large amount of light in the pixel isolation portion. Accordingly, a quantum efficiency may be improved by increasing an amount of light reaching the photoelectric converter, thereby improving image sensing performance of the image sensor. A part of the pixel isolation portion may be a part that has an electrical connection structure capable of applying a negative voltage, and another part of the pixel isolation portion may be a part in which a total reflection is induced by the inner layer having a refractive index lower than a refractive index of the conductive layer. Accordingly, a dark current and a crosstalk may be reduced. Therefore, the performance of the image sensor may be improved.

According to some example embodiments, the pixel isolation portions having different stacking structures may be formed by using width differences without an additional process. The image sensor with enhanced performance may be formed through an easy manufacturing process, thereby reducing manufacturing costs and/or reducing complexity of the manufacturing process, which may result in reduced likelihood of process defects in manufactured image sensors and thus result in improved reliability of such manufactured image sensors.

### BRIEF DESCRIPTION OF THE DRAWINGS

FIG. 1 is a block diagram schematically illustrating an example of an image sensor according to some example embodiments.

FIG. 2 is a plan view schematically illustrating an image sensor according to some example embodiments.

FIG. 3 is a cross-sectional view along lines A-A′, B-B′, and C-C′ in FIG. 2 according to some example embodiments.

FIG. 4 is a cross-sectional view illustrating a first portion, a second portion, and a third portion of a pixel isolation portion included in the image sensor illustrated in FIG. 2 according to some example embodiments.

FIG. 5 is a plan view along a line D-D′ in FIG. 3 according to some example embodiments.

FIG. 6 is a plan view along a line E-E′ in FIG. 3 according to some example embodiments.

FIG. 7 is a perspective view schematically illustrating an example of an inner layer included in the second portion or the third portion of the pixel isolation portion illustrated in FIG. 4 according to some example embodiments.

FIGS. 8A, 8B, 8C, 8D, 8E, 8F, 8G, and 8H are cross-sectional views illustrating a manufacturing method of an image sensor according to some example embodiments.

FIG. 9 is a cross-sectional view of an image sensor according to some example embodiments.

FIG. 10 is a cross-sectional view illustrating a pixel isolation portion included in an image sensor according to some example embodiments.

FIG. 11 is a cross-sectional view illustrating a pixel isolation portion included in an image sensor according to some example embodiments.

FIG. 12 is a cross-sectional view illustrating a pixel isolation portion included in an image sensor according to some example embodiments.

FIG. 13 is a plan view of an image sensor according to some example embodiments.

FIG. 14 is a plan view of an image sensor according to some example embodiments.

FIG. 15 is a plan view of an image sensor according to some example embodiments.

### DETAILED DESCRIPTION

Some example embodiments of the present inventive concepts will be described more fully hereinafter with reference to the accompanying drawings for those skilled in the art to which the present inventive concepts pertain to easily practice the present inventive concepts. The present inventive concepts may be implemented in various different forms and are not limited to the example embodiments described herein.

A portion unrelated to the description is omitted in order to clearly describe the present inventive concepts, and the same or similar components are denoted by the same reference numeral throughout the present specification.

Further, since sizes and thicknesses of portions, regions, members, units, layers, films, etc. illustrated in the accompanying drawings may be arbitrarily illustrated for better understanding and convenience of explanation, the present inventive concepts are not limited to the illustrated sizes and thicknesses. In the drawings, thicknesses of portions, regions, members, units, layers, films, etc. may be enlarged or exaggerated for convenience of explanation.

It will be understood that when a component such as a layer, film, region, or substrate is referred to as being “on” another component, it may be directly on other components or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, and variations such as “comprises” or “comprising”, will be understood to imply the inclusion of stated elements but not the exclusion of any other elements.

Further, throughout the specification, a phrase “on a plane”, “in a plane”, “on a plan view”, or “in a plan view” may indicate a case where a portion is viewed from above or a top portion, and a phrase “on a cross-section” or “in a cross-section” may indicate when a cross-section taken along a vertical direction is viewed from a side.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values or shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

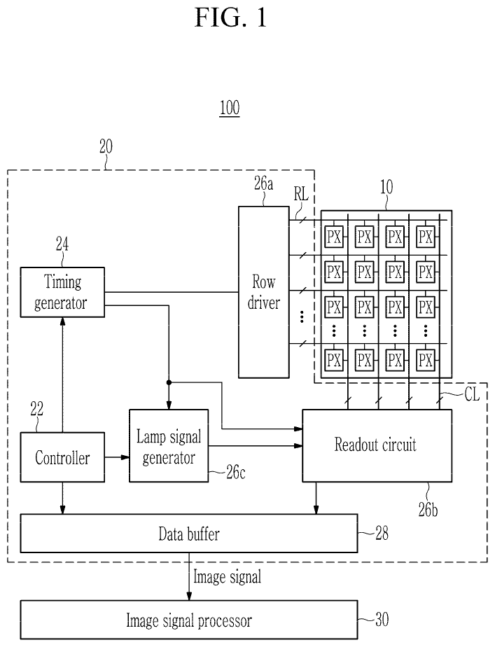

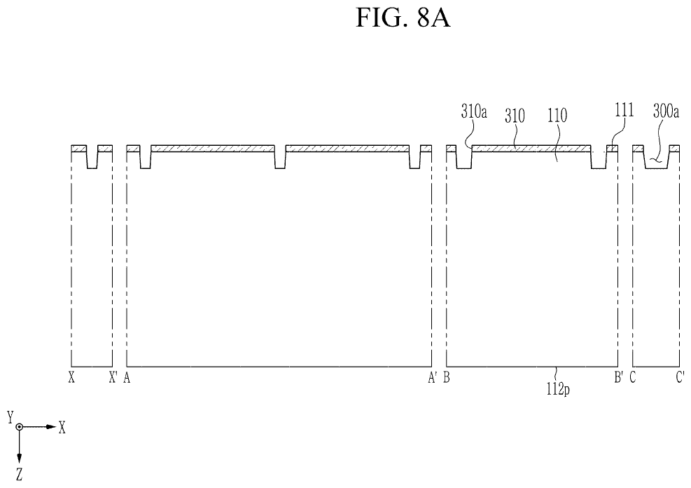

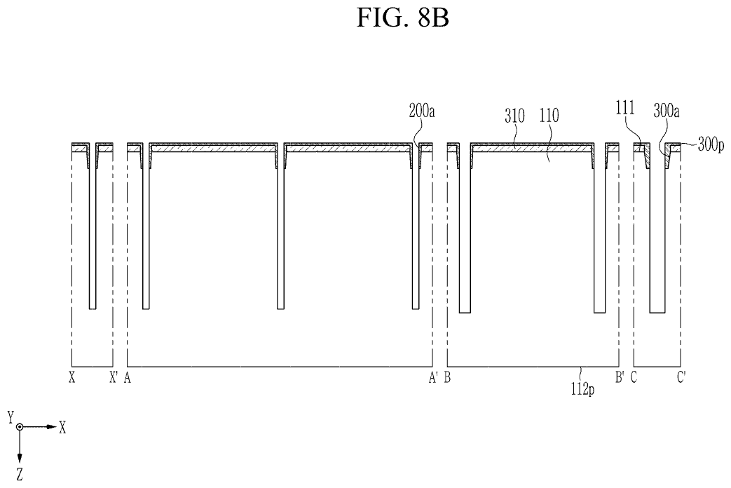

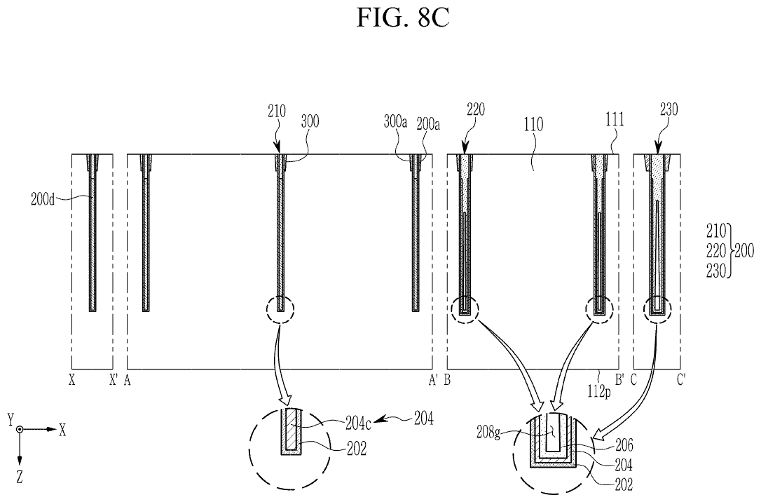

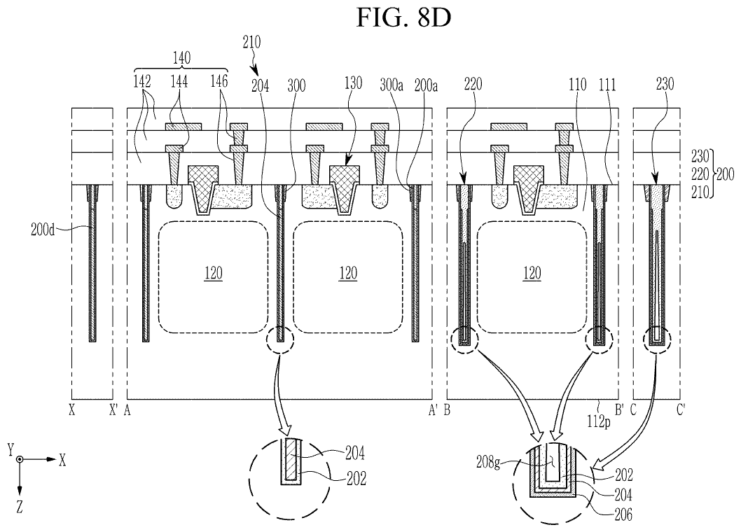

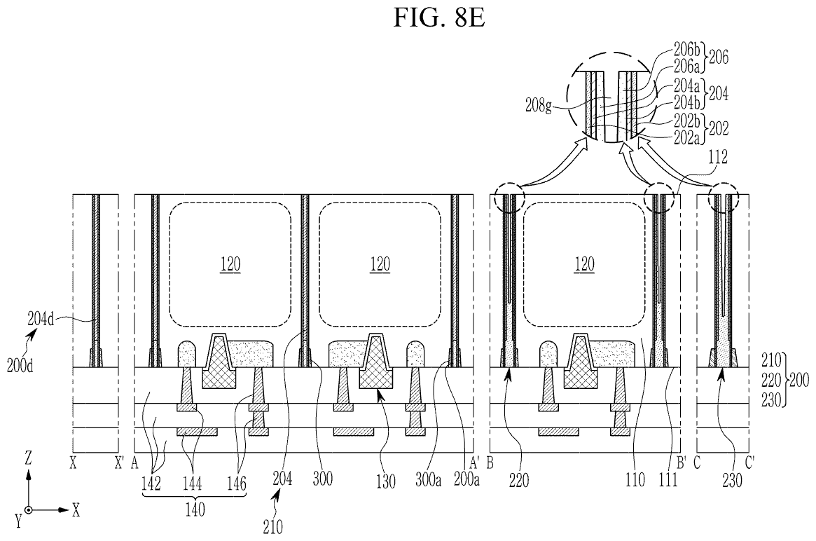

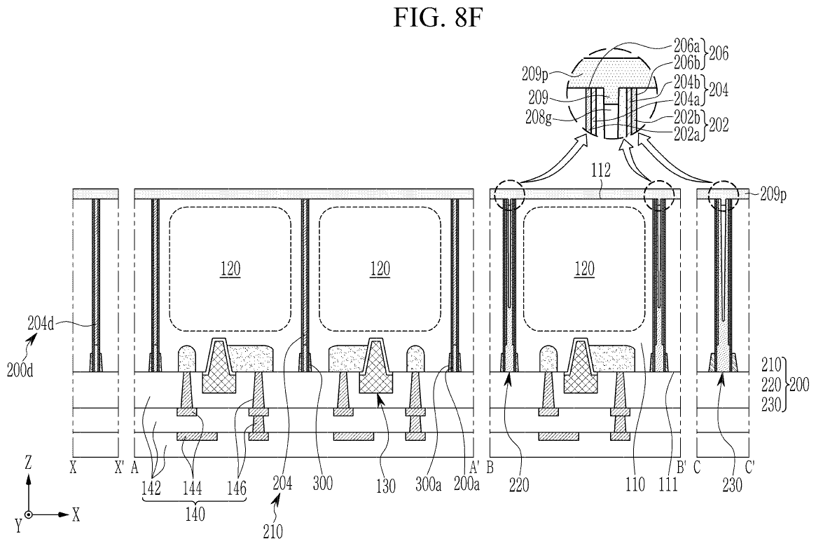

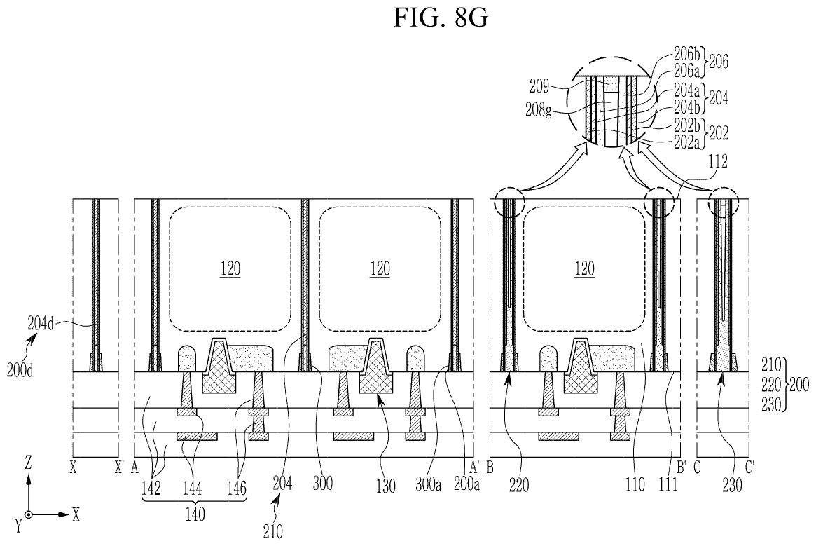

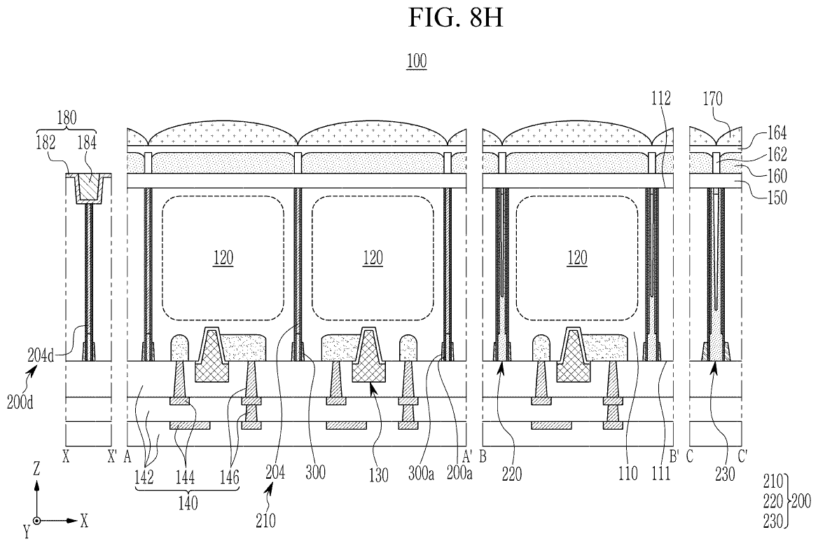

Hereinafter, image sensors and manufacturing methods thereof according to some example embodiments will be described in detail with reference to FIG. 1 to FIG. 7, and FIG. 8A to FIG. 8H.

FIG. 1 is a block diagram schematically illustrating an example of an image sensor according to some example embodiments.

Referring to FIG. 1, an image sensor 100 according to some example embodiments may include a pixel array 10, and a logic circuit 20 of controlling the pixel array 10. The logic circuit 20 is a circuit for controlling the pixel array 10 and may include, for example, a controller 22, a timing generator 24, a row driver 26a, a readout circuit 26b, a lamp signal generator 26c, and a data buffer 28. Also, the image sensor 100 may further include an image signal processor 30. In some example embodiments, the image signal processor 30 may be positioned outside the image sensor 100.

The image sensor 100 may generate an image signal by converting light received from the outside into an electric signal, and the image signal generated by the image sensor 100 may be provided to the image signal processor 30.

The image sensor 100 may be mounted on an electronic device with an image or light sensing function. For example, the image sensor 100 may be mounted on electronic devices such as cameras, smartphones, wearable devices, internet of things (IoT) devices, home appliance devices, tablets, personal digital assistants (PDA), portable multimedia players (PMP), navigations, drones, or advanced driver assistance systems (ADAS). In some example embodiments, the image sensor 100 may be mounted on an electronic device provided as a part of a vehicle, a furniture, a manufacturing facility, a door, or various measuring devices.

The pixel array 10 may include a plurality of pixel regions PX, and a plurality of row lines RL and a plurality of column lines CL respectively connected to the plurality of pixel regions PX.

In some example embodiments, each pixel region PX may include at least one photoelectric conversion device. The photoelectric conversion device may detect incident light and convert the incident light into an electric signal according to the amount of light, that is, into a plurality of analog pixel signals. The photoelectric conversion device may be a photodiode or a pinned diode. In some example embodiments, the photoelectric conversion device may be a single-photon avalanche diode (SPAD) applied to a 3D sensor pixel. A level of the analog pixel signal output from the photoelectric conversion device may be proportional to the amount of light provided to each pixel region PX or the amount of charge output from the photoelectric conversion device.

The plurality of row lines RL may extend in one direction and be connected to the plurality of pixel regions PX arranged along the one direction. For example, a control signal output from the row driver 26a to the row line RL may be transmitted to a gate of a transistor of the plurality of pixel regions PX connected to the row line RL. The column line CL may extend in a direction that intersects the one direction and may be connected to the plurality of pixel regions PX arranged along the direction that intersects the one direction. The plurality of pixel signals output from the plurality of pixel regions PX may be transmitted to the readout circuit 26b through the plurality of column lines CL.

In some example embodiments, the plurality of pixel regions PX may be grouped in a form of a plurality of columns and a plurality of rows to form one unit pixel group. In other words, the plurality of pixels arranged in an extension direction of the row line RL and the plurality of pixels arranged in an extension direction of the column line CL may form one unit pixel group. For example, one unit pixel group includes a plurality of pixels arranged in the form of two columns and two rows, and one unit pixel group may output one analog pixel signal. However, the example embodiments are not limited thereto and various modifications are possible.

According to some example embodiments, each pixel region PX may include a pixel circuit that processes the charge generated by the photoelectric conversion device and outputs an electric signal. The pixel circuit may include a transmission transistor, a reset transistor, a selection transistor, a driving transistor, etc. The example embodiments are not limited thereto and the pixel circuit may have various structures.

The controller 22 may generally control the timing generator 24, the row driver 26a, the readout circuit 26b, the lamp signal generator 26c, and the data buffer 28 included in the image sensor 100. For example, the controller 22 may control an operation timing by using a control signal. In some example embodiments, the controller 22 may receive a mode signal indicating an imaging mode from an application processor and generally control the image sensor 100 based on the received mode signal.

The timing generator 24 may generate a signal that serves as a reference for the operation timing of the image sensor 100. The timing generator 24 may provide a control signal that controls the timing of the row driver 26a, the readout circuit 26b, and the lamp signal generator 26c.

The row driver 26a may generate a control signal to drive the pixel array 10 in response to the control signal of the timing generator 24, and may provide the control signal to the plurality of pixel regions PX of the pixel array 10 through the plurality of row lines RL. For example, the row driver 26a may generate a transmission signal that controls the transmission transistor, a reset control signal that controls the reset transistor, and a selection control signal that controls the selection transistor, and provide the transmission signal, the reset control signal, the selection control signal to the pixel array 10.

The readout circuit 26b may convert the pixel signal (or an electric signal) output through the corresponding column line CL into a pixel value representing the amount of light. The lamp signal generator 26c may generate a reference signal or a lamp signal and transmit the reference signal or the lamp signal to the readout circuit 26b. For example, the readout circuit 26b may convert the pixel signal to a pixel value by comparing the lamp signal and the pixel signal. The pixel value may be an image data with a plurality of bits.

The data buffer 28 may store the pixel value of the pixel region PX transmitted from the readout circuit 26b and may output the stored pixel value in response to a signal from the controller 22.

The image signal processor 30 may perform an image signal processing on the image signal received from the data buffer 28. For example, the image signal processor 30 may receive a plurality of image signals from the data buffer 28 and generate one image by combining the received image signals.

As described herein, any devices, systems, modules, portions, units, controllers, circuits, and/or portions thereof according to any of the example embodiments, and/or any portions thereof (including, without limitation, the image sensor 100, the pixel array 10, the logic circuit 20, the controller 22, the timing generator 24, the row driver 26a, the readout circuit 26b, the lamp signal generator 26c, the data buffer 28, the image signal processor 30, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

The image sensor 100 described above is an example, and a structure, a type, a kind or so on of the image sensor 100 may be modified in various ways.

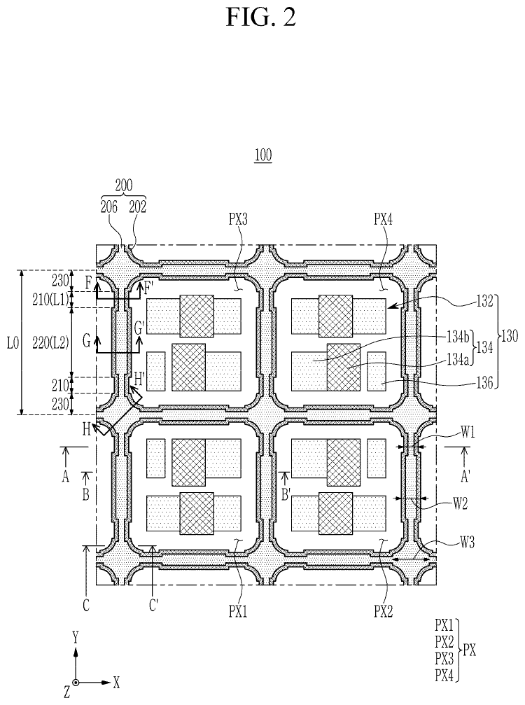

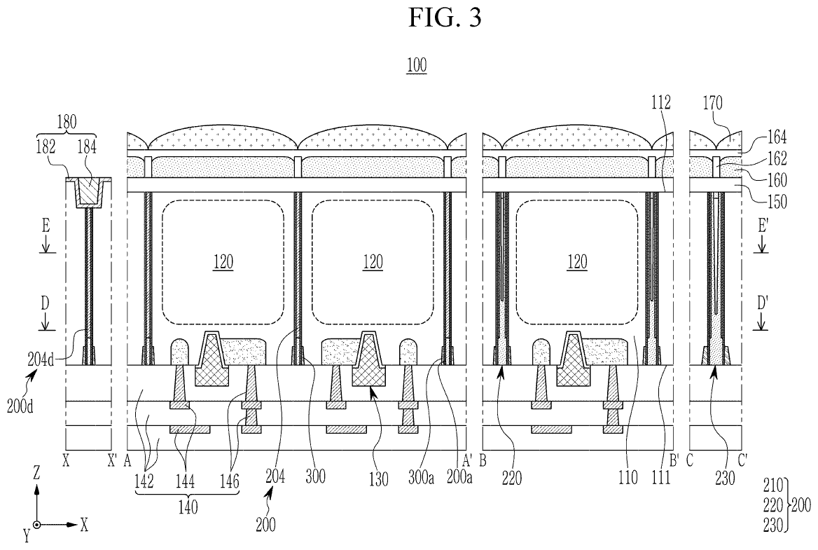

The image sensor 100 (more particularly, the pixel array 10) according to some example embodiments is explained in more detail with reference to FIG. 2 and FIG. 3.

FIG. 2 is a plan view schematically illustrating an image sensor 100 according to some example embodiments. FIG. 3 is a cross-sectional view along lines A-A′, B-B′, and C-C′ in FIG. 2 according to some example embodiments. FIG. 2 illustrates a first surface 111 of a substrate 110 adjacent to a wiring portion 140 as a reference, and a device isolation portion 300 is omitted for a simple illustration and a clear understanding. A dummy pixel isolation portion 200d provided in a dummy cell outside the plurality of pixel regions PX and a contact portion 180 of applying a voltage to the dummy pixel isolation portion 200d are additionally illustrated in a part X-X′ of FIG. 3.

Referring to FIG. 2 and FIG. 3, in some example embodiments, the image sensor 100 may include a substrate 110 including a plurality of pixel regions PX, a photoelectric converter 120 at the substrate 110, and a pixel isolation portion 200 that separates the plurality of pixel regions PX.

In some example embodiments, the substrate 110 may include a semiconductor substrate including a semiconductor material. For example, the substrate 110 may be a bulk substrate including a semiconductor material, a substrate with an epitaxial layer formed on a bulk substrate, or a semiconductor-on-insulator. In some example embodiments, the semiconductor material provided in the substrate 110 may include a first conductivity type dopant to have a first conductivity type (e.g., a P-type or an N-type).

The semiconductor material included in the substrate 110 may include at least one of a group IV semiconductor, a group III-V compound semiconductor, or a group II-VI compound semiconductor. For example, the semiconductor material included in the substrate 110 may include at least one of Si, Ge, SiGe, SiC, GaAs, InAs, GaP, InP, InSb, InGaAs, ZnTe, or CdS. As an example, the bulk substrate may be a single-crystalline or polycrystalline semiconductor substrate and may include Si, Ge, or SiGe. For example, the semiconductor-on-insulator may be a silicon-on-insulator (SOI), a germanium-on-insulator (SGOI), or a silicon-germanium-on-insulator (SGOI).

In some example embodiments, the plurality of pixel regions PX included in the substrate 110 may include a first pixel region PX1 and a second pixel region PX2 adjacent in a first direction (an X-axis direction of the drawing), and may further include a third pixel region PX3 and a fourth pixel region PX4 respectively adjacent to the first pixel region PX1 and the second pixel region PX2 in a second direction (a Y-axis direction in the drawing) intersecting the first direction (the X-axis direction of the drawing). For example, the first pixel region PX1, the second pixel region PX2, the third pixel region PX3, and the fourth pixel region PX4 illustrated in FIG. 2 may form one unit pixel group, but the example embodiments are not limited thereto.

The photoelectric converter 120 for converting light incident from the outside into an electrical signal may be in the substrate 110 (e.g., at the substrate 110). The photoelectric converter 120 may include including a second conductivity type dopant to have a second conductivity type (e.g., an N-type or a P-type) opposite to the first conductivity type of the substrate 110.

The substrate 110 and the photoelectric converter 120 may form a photodiode. The photodiode may be formed by a pn junction of the substrate 110 having the first conductivity type and the photoelectric converter 120 having the second conductivity type. The photoelectric converter 120, which constitutes the photodiode, may generate and accumulate charges in proportion to the amount of light provided to each pixel region PX.

The photoelectric converter 120 may correspond to each pixel region PX by a device isolation portion 300. For example, the device isolation portion 300 may be in a first trench 300a, which has a first depth, to define an active region in each pixel region PX. For example, the first trench 300a may be a shallow trench (ST). The device isolation portion 300 may include at least one of silicon oxide, silicon nitride, or silicon oxynitride, and the device isolation portion 300 may include a single layer or a plurality of layers. However, the example embodiments are not limited thereto. Therefore, the material of the device isolation portion 300 may be modified in various ways, or the device isolation portion 300 might not be provided.

A pixel isolation portion 200 (also referred to herein interchangeably as a pixel isolation structure) that passes through (e.g., penetrates) at least a part of the substrate 110 and separates the plurality of pixel regions PX may be between the plurality of pixel regions PX. In some example embodiments, the pixel isolation portion 200 may be formed by penetrating a part (e.g., a central portion) of the device isolation portion 300.

In some example embodiments, the pixel isolation portion 200 may include a first pixel isolation portion extending in the first direction (the X-axis direction of the drawing) and a second pixel isolation portion extending in the second direction (the Y-axis direction of the drawing). For example, the pixel isolation portion 200 may have a lattice shape that partitions the plurality of pixel regions PX and thus may separate at least two pixel regions that are adjacent to each other. As a result, each pixel region PX may be surrounded by a pair of first pixel isolation portions and a pair of second pixel isolation portions.

The pixel isolation portion 200 may be in a second trench 200a, which has a second depth greater than the first depth, to define the pixel region PX. For example, the second trench 200a may be a deep trench (DT). In some example embodiments, the pixel isolation portion 200 may be a front deep trench isolation (FDTI) formed from a first surface 111 of the substrate 110. For example, the pixel isolation portion 200 may extend from the first surface 111 of the substrate 110 to a second surface 112 of the substrate 110. However, the example embodiments are not limited thereto. The pixel isolation portion 200 does not extend to the second surface 112 to be positioned at a part of the substrate 110 in a thickness direction of the substrate 110. In some example embodiments, the pixel isolation portion 200 may further include a back deep trench isolation (BDTI) formed from the second surface 112 of the substrate 110.

In some example embodiments, the pixel isolation portion 200 may include a conductive layer 204. Based on applying a negative voltage to the conductive layer 204 of the pixel isolation portion 200, a dark current may be improved through a hole accumulation, thereby improving image sensing performance of the image sensor 100.

A dummy cell and a dummy pixel isolation portion 200d to separate the dummy cell may be in an external region of the plurality of pixel regions PX. In some example embodiments, the dummy pixel isolation portion 200d may include a conductive layer 204d connected to the conductive layer 204 of the pixel isolation portion 200, as an example, the conductive layer 204d of the dummy pixel isolation portion 200d may be formed together in a process of forming the conductive layer 204 of the pixel isolation portion 200. Accordingly, the conductive layer 204d of the dummy pixel isolation portion 200d may include the same material as the conductive layer 204 of the pixel isolation portion 200. However, the example embodiments are not limited thereto, the conductive layer 204d of the dummy pixel isolation portion 200d may be formed in a process different from a process of forming the conductive layer 204 of the pixel isolation portion 200, or may include a different material from the conductive layer 204.

In a portion where the dummy pixel isolation portion 200d is positioned, a contact portion 180, which is electrically connected to the conductive layer 204d of the dummy pixel isolation portion 200d, may be on the second surface 112 side of the substrate 110. The contact portion 180 may be a portion connected to the conductive layer 204d of the dummy pixel isolation portion 200d and applying a negative voltage to the conductive layer 204 of the pixel isolation portion 200 through the conductive layer 204d of the dummy pixel isolation portion 200d.

In some example embodiments, a contact trench may be on the second surface 112 of the substrate 110. The contact portion 180 may include a wiring layer 182 on the second surface 112 and an inner surface of the contact trench, and a pad 184 on the wiring layer 182 in the contact trench and filling the remaining portion of the contact trench. The wiring layer 182 may be connected to the wiring portion 140 through the substrate 110 or may be connected to an external circuit. The wiring layer 182 may be electrically connected to the conductive layer 204d of the dummy pixel isolation portion 200d. The conductive layer 204d and the contact portion 180 may be stably connected by the contact trench.

The wiring layer 182 or the pad 184 may include a conductive material. For example, the wiring layer 182 or pad 184 may include at least one of copper, aluminum, tungsten, nickel, gold, tin, manganese, cobalt, titanium, tantalum, ruthenium, or beryllium, or an alloy including the same. As an example, the wiring layer 182 may include tungsten and the pad 184 may include aluminum. However, the example embodiments are not limited to the materials of the wiring layer 182 and the pad 184.

The above-described structure is an example of a structure that applies the negative voltage to the conductive layer 204d of the dummy pixel isolation portion 200d, and the example embodiments are not limited thereto. That is, in some example embodiments, it is described that the pad 184 is electrically connected to the conductive layer 204d of the dummy pixel isolation portion 200d through the wiring layer 182, but the pad 184 may be in a direct contact with the conductive layer 204d of the dummy pixel isolation portion 200d. Other various modifications are possible.

In the drawing, it is illustrated that a surface of the device isolation portion 300 and a surface of the pixel isolation portion 200 are positioned on the same plane as (e.g., are coplanar with) the first surface 111 of the substrate 110 at a side of the first surface 111 of the substrate 110. However, the example embodiments are not limited thereto, and the first surface 111 of the substrate 110, and the surface of the device isolation portion 300 and/or the surface of the pixel isolation portion 200 may be positioned on different planes from each other.

The pixel circuit 130 may be at the first surface 111 side of the substrate 110. More particularly, the pixel circuit 130 may be at an inside of the pixel region PX defined by the pixel isolation portion 200 and/or the device isolation portion 300. For example, the pixel circuit 130 may include at least one transistor 132, a transmission transistor 134, and a doping region 136.

The transmission transistor 134 may be at the first surface 111 of the substrate 110. The transmission transistor 134 may be electrically connected to the photoelectric converter 120. The transmission transistor 134 may include a transmission gate structure 134a and a floating diffusion region 134b. The floating diffusion region 134b may have a second conductivity type opposite to the first conductivity type of the substrate 110, and charges generated by the photoelectric converter 120 may be accumulated. The floating diffusion region 134b may be adjacent to at least one side of the transmission gate structure 134a. A shape of floating diffusion region 134b is not limited as illustrated in FIG. 2 and may be modified in various ways in some example embodiments.

The transmission gate structure 134a may control such that the charge generated in the photoelectric converter 120 moves or does not move to the floating diffusion region 134b depending on the applied voltage. The transmission gate structure 134a may include a transmission gate electrode, a gate dielectric layer, and/or a gate spacer.

The transistor 132 may include at least one of a reset transistor, a selection transistor, or a driving transistor included in the pixel circuit. The transistor 132 may include a gate structure and a source and drain region at both sides of the gate structure. As an example, the pixel circuit 130 may be implemented by sharing the transistor 132 by the plurality of pixel regions PX adjacent to each other.

The doping region 136 may be separated from the floating diffusion region 134b and the transistor 132. The doping region 136 may be doped with the first conductivity type dopant and have the same conductivity type as the conductivity type of the substrate 110, and a ground voltage may be applied to the doping region 136.

The above pixel circuit 130 is an example, and the example embodiments are not limited thereto. Therefore, the pixel circuit 130 may have various structures or arrangements.

The wiring portion 140 may be on the first surface 111 of the substrate 110. The wiring portion 140 may include a plurality of wiring layers 144 with the interlayer insulating layer 142 therebetween, and a contact via 146 connecting the plurality of wiring layer 144 while passing through an interlayer insulating layer 142. The wiring layer 144 and the contact via 146 may be connected to form a desired circuit. The contact via 146 may be formed in the same process as the wiring layer 144, or may be formed in a separate process from the wiring layer 144. The wiring portion 140 may be electrically connected to the pixel circuit 130.

The interlayer insulating layer 142 may include an insulating material. For example, the interlayer insulating layer 142 may include silicon oxide, silicon nitride, silicon oxynitride, and a low dielectric constant material. Here, the low dielectric constant material may be a material having a dielectric constant lower than a dielectric constant of silicon oxide.

The wiring layer 144 or the contact via 146 may include at least one of a metal, a metal alloy, a metal nitride, a metal silicide, or a doped semiconductor material. Here, the metal or the metal alloy may include at least one of tungsten, molybdenum, aluminum, copper, or cobalt, and the metal nitride may include at least one of tungsten nitride, molybdenum nitride, titanium nitride, or tantalum nitride. The wiring layer 144 or the contact via 146 may further include metal oxide or metal oxynitride in which the above material is oxidized. The wiring layer 144 or the contact via 146 may include a single layer or a plurality of layers.

However, the example embodiments are not limited thereto, and the interlayer insulating layer 142 may include various insulating materials, and the wiring layer 144 or the contact via 146 may include various conductive materials.

According to some example embodiments, a support substrate or a logic chip including a logic circuit may be further provided on the wiring portion 140. However, the support substrate might not be provided, or the image sensor 100 may be next to the logic chip. Other various modifications are possible.

On the second surface 112 of the substrate 110, a horizontal insulation layer 150, a color filter 160, a filter isolation portion 162, a planarization layer 164, and a micro lens 170 may be included.

More particularly, the horizontal insulation layer 150 may be on the second surface 112 of the substrate 110. The horizontal insulation layer 150 may cover the second surface 112 of the substrate 110 and the pixel isolation portion 200.

The horizontal insulation layer 150 may include various insulating materials. For example, an anti-reflection layer may include oxide, nitride, oxynitride, or fluoride including at least one of hafnium, zirconium, aluminum, tantalum, titanium, yttrium, cerium, lanthanum, neodymium, praseodymium, ytterbium, or silicon. As an example, the horizontal insulation layer 150 may serve as an anti-reflection layer, but the example embodiments are not limited thereto.

In some example embodiments, the horizontal insulation layer 150 may include a plurality of layers including different materials and having different thicknesses. For example, in the horizontal insulation layer 150, a first horizontal insulation layer adjacent to the second surface 112 of the substrate 110 may be a fixed charge layer having a negative fixed charge. Then, the dark current may be improved (e.g., reduced) by a hole accumulation at a periphery of the fixed charge layer, thereby improving image sensing performance of the image sensor 100. In some example embodiments, the first horizontal insulation layer may include a metal oxide or a metal fluoride including at least one of hafnium, zirconium, aluminum, tantalum, titanium, or yttrium. As an example, the horizontal insulation layer 150 or the anti-reflection layer may include a first horizontal insulation layer including hafnium oxide, a second horizontal insulation layer including silicon oxide or silicon nitride, and a third horizontal insulation layer including hafnium oxide. However, the example embodiments are not limited thereto, and a number, a thickness, or so on of the layers included in the horizontal insulation layer 150 may be varied in various ways.

The filter isolation portion 162 may be on the horizontal insulation layer 150. When viewed in a plan view, the filter isolation portion 162 may be at a position that overlaps with a part of the pixel isolation portion 200. The filter isolation portion 162 may be at a boundary of the color filter 160 and, for example, may surround at least a part of the color filter 160. For example, the filter isolation portion 162 may have the same or similar lattice structure as the pixel isolation portion 200, but the example embodiments are not limited thereto. The filter isolation portion 162 may also be referred to as a fence pattern or a grid pattern.

The filter isolation portion 162 may prevent light incident obliquely into one color filter 160 in one of the plurality of pixel regions PX from entering another color filter 160 in another adjacent pixel region PX, or reduce or minimize such entering of such light into the other adjacent pixel region PX. Accordingly, a crosstalk between the plurality of pixel regions PX may be reduced, minimized, or prevented, thereby improving image sensing performance of the image sensor 100.

In some example embodiments, the filter isolation portion 162 may include a material having a refractive index smaller than the refractive index of the color filter 160 or silicon oxide, or a material having a refractive index of about 1.0 to about 1.4. In this way, if the filter isolation portion 162 includes a material with a small refractive index, the light incident on the filter isolation portion 162 may be totally reflected and directed to the inner direction of the pixel region PX.

For example, the filter isolation portion 162 may include polymethyl methacrylate (PMMA), silicon acrylate, cellulose acetate butyrate (CAB), silica, or fluorine-silicon acrylate (FSA). For example, the filter isolation portion 162 may include a polymer material in which silica particles are dispersed. However, the example embodiments are not limited thereto, and the filter isolation portion 162 may include a material different from the above material.

The plurality of color filters 160 may be on the horizontal insulation layer 150 and may be separated from each other by the filter isolation portion 162. The plurality of color filters 160 may include, for example, a green filter, a blue filter, and a red filter. The plurality of color filters 160 may include, for example, cyan, magenta, or yellow. According to some example embodiments, the color filter 160 may further include an infrared filter for passing infrared light.

The planarization layer 164 may be on the color filter 160, and the micro lens 170 may be on the planarization layer 164. The planarization layer 164 may include various materials such as organic material, silicon oxide, and silicon oxynitride. However, the example embodiments are not limited to the material of the planarization layer 164, and the planarization layer 164 might not be provided (e.g., might be omitted).

The micro lens 170 may include a portion having a convex shape to converge or concentrate light incident on the pixel region PX. The micro lens 170 may include various resin materials, for example, styrene-based resin, acryl-based resin, styrene-acryl copolymer resin, or siloxane-based resin. However, the example embodiments are not limited thereto, and a shape, a material, or so on of the micro lens 170 may be modified in various ways.

In the drawing, it is illustrated that the micro lens 170 corresponds to each of the plurality of pixel regions PX. However, the example embodiments are not limited thereto, and one micro lens 170 may correspond to the plurality of pixel regions PX. According to some example embodiments, a protective layer, etc. may be further on an outer surface of the micro lens 170.

In the image sensor 100 according to some example embodiments, light incident from the outside may be converged or concentrated by the micro lens 170 and may be incident on the photoelectric converter 120 through the color filter 160. Light incident on the photoelectric converter 120 may be converted into an electric signal depending on the amount of light.

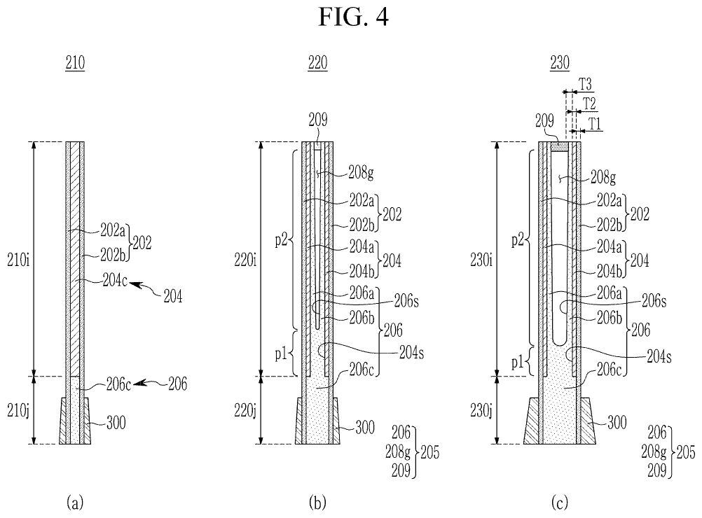

The pixel isolation portion 200 according to some example embodiments may have a first portion 210, a second portion 220 and/or a third portion 230 in which parts between two adjacent pixel regions PX have different structures. This will be explained in detail with reference to FIG. 4 to FIG. 7 along with FIG. 2 and FIG. 3.

Hereinafter, the pixel isolation portion 200 extending in the second direction (the Y-axis direction of the drawing) between the first pixel region PX1 and the second pixel region PX2 at one side (the right of FIG. 2) of the first pixel region PX1 will be described as a reference. The below explanation may be applied to at least one of the plurality of pixel isolation portions 200 extending in the second direction between two pixel regions PX adjacent in the first direction (the X-axis direction of the drawing). Also, the below explanation may be respectively applied to at least one of the plurality of pixel isolation portions 200 extending in the first direction between two pixel regions PX adjacent in the second direction. For example, the below explanation may be applied to the pixel isolation portion 200 extending in the first direction between the first pixel region PX1 and the third pixel region PX3 or between the second pixel region PX2 and the fourth pixel region PX4. That is, the below description of the pixel isolation portion 200 may be applied to at least one of the plurality of pixel isolation portions 200 surrounding one pixel region PX.

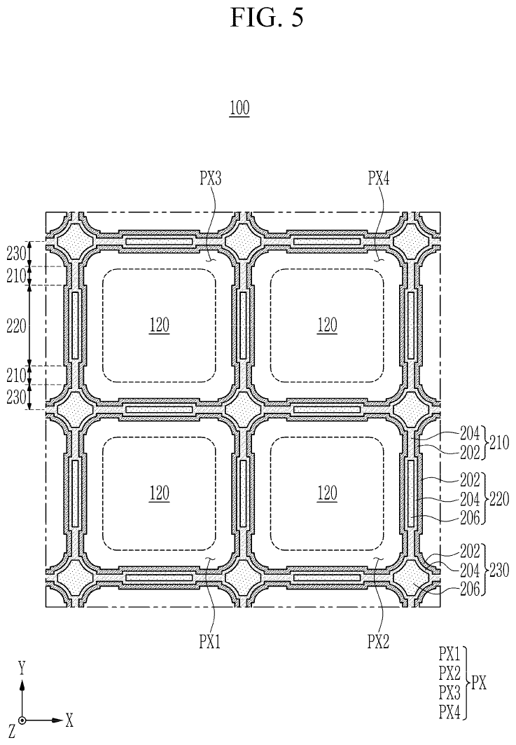

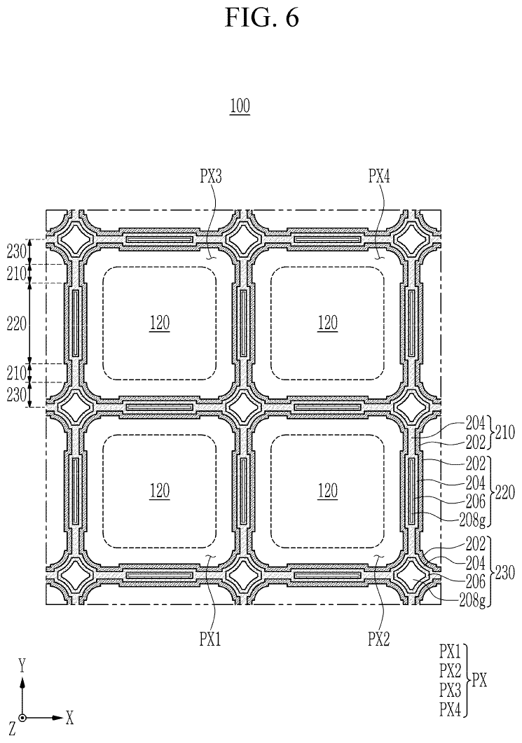

FIG. 4 is a cross-sectional view illustrating the first portion 210, the second portion 220, and the third portion 230 of the pixel isolation portion 200 included in the image sensor 100 illustrated in FIG. 2 according to some example embodiments. In some example embodiments, (a) of FIG. 4 illustrates the first portion 210 of the pixel isolation portion 200 along with the device isolation portion 300 along line F-F′ in FIG. 2, (b) of FIG. 4 illustrates the second portion 220 of the pixel isolation portion 200 along with the device isolation portion 300 along line G-G′ in FIG. 2, and (c) of FIG. 4 illustrates the third portion 230 of the pixel isolation portion 200 along with the device isolation portion 300 along line H-H′ in FIG. 2. FIG. 5 is a plan view along line D-D′ in FIG. 3 according to some example embodiments. FIG. 6 is a plan view along line E-E′ in FIG. 3 according to some example embodiments.

Referring to FIG. 4 to FIG. 6 along with FIG. 2 and FIG. 3, the pixel isolation portion 200 may include first and second insulation portions 202a and 202b respectively adjacent to the pixel regions PX adjacent in an intersection direction intersecting the pixel isolation portion 200 (e.g., the first insulation portion 202a is adjacent to a first pixel region PX at one side of the pixel isolation portion 200 and the second insulation portion 202b is adjacent to a second pixel region PX at an opposite side of the pixel isolation portion 200), and a conductive layer 204 and an inner layer 205 and including different materials between the first and second insulation portions 202a and 202b. Hereinafter, the pixel regions PX adjacent to each other in the intersection direction intersecting the pixel isolation portion 200 will be referred to as a first pixel region PX1 and a second pixel region PX2, respectively. In some example embodiments, the intersection direction may be a direction that intersects an extension direction of the pixel isolation portion 200. For example, the intersection direction may include at least one of the X-axis direction or the Y-axis direction in the drawings, although the example embodiments are not limited thereto.

The first insulation portion 202a or the second insulation portion 202b may include various insulating materials. In some example embodiments, the first insulation portion 202a or the second insulation portion 202b may include oxide, nitride, oxynitride, etc., and more particularly, include an insulating material including silicon (e.g., silicon oxide, silicon nitride, silicon oxynitride, etc.). However, the example embodiments are not limited to a material of the first insulation portion 202a or the second insulation portion 202b.

The conductive layer 204 may include various conductive materials. For example, the conductive layer 204 may include a semiconductor material (e.g., polycrystalline semiconductor, for example, polysilicon) including a dopant. The dopant included in the conductive layer 204 may be an N-type dopant or a P-type dopant, for example, a P-type dopant. As an example, the conductive layer 204 may be polysilicon including boron, aluminum, gallium, indium, etc. However, the example embodiments are not limited to the material of the conductive layer 204.

In some example embodiments, the inner layer 205 may include a different material from the conductive layer 204 and may have a different refractive index than a refractive index of the conductive layer 204. For example, the inner layer 205 may have a refractive index that is smaller than a refractive index of the conductive layer 204. For example, the refractive index of the inner layer 205 may be 4.0 or less (e.g., 0 to 4.0, 0.01 to 4.0, 0.1 to 4.0, etc.). In some example embodiments, the inner layer 205 may include at least one of an inner insulation layer 206 including an insulating material or a space portion 208g having an inner space. In addition, the inner layer 205 may further include an end insulation portion 209 at one end of the space portion 208g (e.g., an end adjacent to the second surface 112 of the substrate 110). For example, the inner layer 205 may include the end insulation portion 209 which may define one end of the space portion 208g as shown in (b) and (c) of FIG. 4, the end insulation portion 209 may include a surface at least partially defining one end of the space portion 208g.

The end insulation portion 209 may block one end of the space portion 208g at the second surface 112 of the substrate 110 to prevent other unwanted materials from being formed within the space portion 208g in a subsequent process of forming the horizontal insulation layer 150, the color filter 160, and the filter isolation portion 162.

The inner insulation layer 206 or the end insulation portion 209 (and thus the inner layer 205) may include any of various insulating materials such as at least one of oxide, nitride, oxynitride, or fluoride. For example, the inner insulation layer 206 or the end insulation portion 209 (and thus the inner layer 205) may include at least one of silicon oxide, silicon nitride, silicon oxynitride, aluminum oxide, or hafnium oxide. However, the example embodiments are not limited to the material of the inner insulation layer 206 or the end insulation portion 209.

In some example embodiments, the pixel isolation portion 200 may include the first portion 210 having a first width W1 and the second portion 220 having a second width W2 that is greater than the first width W1. Also, the pixel isolation portion 200 may further include the third portion 230 with a third width W3 that is greater than the first width W1 and the second width W2.

Here, the first width W1, the second width W2, and the third width W3 may be measured at the same position in the thickness direction (the Z-axis direction of the drawing) of the substrate 110. The first width W1 of the first portion 210 may refer to the minimum width among the widths in the intersection direction that intersects (e.g., is perpendicular to) the pixel isolation portion 200. The second width W2 of the second portion 220 may refer to the maximum width among the widths in the intersection direction that intersects (e.g., is perpendicular to) the pixel isolation portion 200. The third width W3 of the third portion 230 may refer to the minimum width among the widths in the intersection direction that intersects (e.g., is perpendicular to) the pixel isolation portion 200. The intersection direction may extend in a direction that intersects an extension direction of the pixel isolation portion 200.

The third portion 230 may be respectively at both ends of each pixel isolation portion 200 in an extension direction of the pixel isolation portion 200 in a plan view. More particularly, the third portion 230 may be at a corner portion where four pixel regions are adjacent to each other (e.g., a center portion of first to fourth pixel regions PX1, PX2, PX3 and PX4 adjacent in the first direction (the X-axis direction of the drawing) and the second direction (the Y-axis direction of the drawing)). Here, the first and second pixel regions PX1 and PX2 may be adjacent in the first direction, the third and fourth pixel regions PX3 and PX4 may be adjacent in the first direction, and the first and second pixel regions PX1 and PX2 and the third and fourth pixel regions PX3 and PX4 may be adjacent in the second direction.

The third portion 230 may be at the corner portion where the pixel isolation portion 200 extending in the first direction and the pixel isolation portion 200 extending in the second direction intersect, and a width of the third portion 230 may gradually widen as it approaches an end of each pixel isolation portion 200. For example, the third portion 230 may have a rounded shape to have a concave shape with respect to a center direction of the pixel region PX, but the example embodiments are not limited thereto.

The first portion 210 and the second portion 220 are portions between two third portions 230 at both ends of the pixel isolation portion 200, and may have the first widths W1 and the second widths W2, respectively, different from each other, respectively. In some example embodiments, by including the first portion 210 and the second portion 220 having the different widths between the third portions 230 at both ends, and the first portion 210 and the second portion 220 have different stacking structures to perform different roles.

In the drawing, it is described that side surfaces of the first portion 210, the second portion 220, and the third portion 230 are vertical to the substrate 110. However, the example embodiments are not limited thereto, and at least one side surface of the first portion 210, the second portion 220, and the third portion 230 may include an inclined portion inclined to the substrate 110. For example, at least one side surface of the first portion 210, the second portion 220, and the third portion 230 may include an inclined portion so that a width decreases in a direction away from the substrate 110. Other various modifications are possible.

In some example embodiments, the first portion 210 may include a first isolation portion 210j adjacent to the first surface 111 of the substrate 110, and a first inner portion 210i extending from the first isolation portion 210j toward the second surface 112 of the substrate 110. The second portion 220 may include a second isolation portion 220j adjacent to the first surface 111 of the substrate 110, and a second inner portion 220i extending from the second isolation portion 220j toward the second surface 112 of the substrate 110. The third portion 230 may include a third isolation portion 230j adjacent to the first surface 111 of the substrate 110, and a third inner portion 230i extending from the third isolation portion 230j toward the second surface 112 of the substrate 110.

As an example, the first isolation portion 210j, the second isolation portion 220j, and the third isolation portion 230j may pass through at least a part of the device isolation portion 300. The first inner portion 210i, the second inner portion 220i, and the third inner portion 230i may refer to a portion where the conductive layer 204 is positioned.

In some example embodiments, the first isolation portion 210j, the second isolation portion 220j, and the third isolation portion 230j adjacent to the first surface 111 of the substrate 110 may have different widths but the same stacking structure. For example, the first isolation portion 210j, the second isolation portion 220j, and the third isolation portion 230j may be composed of an insulating material.

More particularly, the first isolation portion 210j, the second isolation portion 220j, and the third isolation portion 230j may respectively include the first and second insulation portions 202a and 202b, and the inner insulation layer 206. The first and second insulation portions 202a and 202b may be respectively adjacent to the first and second pixel regions PX1 and PX2. The inner insulation layer 206 may be between the first and second insulation portions 202a and 202b. In some example embodiments, the inner insulation layer 206 of the first isolation portion 210j, the second isolation portion 220j, or the third isolation portion 230j may include a filling insulation portion 206c that fills a space between the first and second insulation portions 202a and 202b. Accordingly, in the intersection direction intersecting the pixel isolation portion 200, the first insulation portion 202a, the filling insulation portion 206c, and the second insulation portion 202b may be sequentially positioned in each of the first isolation portion 210j, the second isolation portion 220j, and the third isolation portion 230j.

By the first isolation portion 210j, the second isolation portion 220j, and the third isolation portion 230j, the conductive layer 204 of the pixel isolation portion 200 and the wiring portion 140 on the first surface 111 of the substrate 110 may be stably insulated.

In some example embodiments, the first inner portion 210i may have a stacking structure different from a stacking structure of the second inner portion 220i and/or the third inner portion 230i.

More particularly, each of the first inner portion 210i, the second inner portion 220i, and the third inner portion 230i may include the first insulation portion 202a on one side surface of the second trench 200a adjacent to the first pixel region PX1 and a second insulation portion 202b on the other side surface of the second trench 200a adjacent to the second pixel region PX2. That is, the first inner portion 210i, the second inner portion 220i, and the third inner portion 230i may include the first and second insulation portions 202a and 202b that is the same or substantially the same.

In some example embodiments, the first insulation portion 202a and the second insulation portion 202b may be portions included in one insulation layer 202 and may be formed through the same process. Accordingly, the first insulation portion 202a and the second insulation portion 202b of the pixel isolation portion 200 may have the same material and the same thickness. For example, the thicknesses of the first insulation portions 202a of the first portion 210, the second portion 220, and the third portion 230 may be the same, and/or the thicknesses of second insulation portions 202b of the first portion 210, the second portion 220, and the third portion 230 may be the same.

Here, the thickness may refer to a thickness measured in a direction perpendicular to a side surface of the second trench 200a where the pixel isolation portion 200 is provided. Here, having the same thickness may include a case where the thickness at the same position in the thickness direction (the Z-axis direction of the drawing) of the substrate 110 is within a process error (for example, within 10%).

However, the example embodiments are not limited thereto. The first insulation portions 202a and/or the second insulation portions 202b of the first portion 210, the second portion 220, and the third portion 230 may include portions having different thicknesses.

In some example embodiments, the conductive layer 204 of the first inner portion 210i may have a different structure from the conductive layer 204 of the second inner portion 220i and/or the third inner portion 230i.

More particularly, the first inner portion 210i may be a portion that does not have the inner layer 205. That is, in the first inner portion 210i, the conductive layer 204 may include a filling conductive portion 204c that fills the space between the first insulation portion 202a and the second insulation portion 202b, for example such that the inner layer 205 is omitted or absent or excluded from the first inner portion 210i. The space between the first insulation portion 202a and the second insulation portion 202b may be entirely filled by the filling conductive portion 204c for example such that the filling conductive portion 204c or the conductive layer 204 occupies an entirety of the space defined between the first and second insulation portions 202a and 202b in the first inner portion 210i (e.g., an entirety of the space in between the first and second insulation portions 202a and 202b in at least the intersection direction in the first inner portion 210i). In some example embodiments, being entirely filled may include a case that there is a portion in which the conductive layer 204 or the filling conductive portion 204c is positioned as a whole in the intersection direction that intersects the pixel isolation portion 200. In some example embodiments, there may be a partial portion where the conductive layer 204 or the filling conductive portion 204c is not positioned between the first insulation portion 202a and the second insulation portion 202b.

For example, in the first inner portion 210i of the first portion 210 having the relatively small first width W1, the filling conductive portion 204c may have a sheet shape or a liner shape having a plane that extends in the extension direction of the pixel isolation portion 200 and the thickness direction of the substrate 110 and having a constant width in the intersection direction that intersects the pixel isolation portion 200. As a result, the first inner portion 210i may stably have an electrical connection structure.

By the filling conductive portion 204c, the first inner portion 210i or the first portion 210 may have an electrical connection structure between the first insulation portion 202a and the second insulation portion 202b. For example, in the first inner portion 210i, the filling conductive portion 204c may at least partially define an electrical connection structure between the first insulation portion 202a and the second insulation portion 202b such that the first portion 210 has an electrical connection structure between the first insulation portion 202a and the second insulation portion 202b that is at least partially defined by the conductive layer 204. That is, a negative voltage may be provided to the first and second pixel regions PX1 and PX2 adjacent to each other by the conductive layer 204 of the pixel isolation portion 200 between the first insulation portion 202a and the second insulation portion 202b.

The inner layer 205 may be at an inside of the conductive layer 204 (e.g., between opposing surfaces 204s of the conductive layer 204) in the second inner portion 220i and/or the third inner portion 230i. That is, in the second inner portion 220i and/or the third inner portion 230i, the conductive layer 204 may include a first conductive portion 204a on the first insulation portion 202a and a second conductive portion 204b on the second insulation portion 202b. In some example embodiments, a space for the inner layer 205 may be positioned between the first conductive portion 204a and the second conductive portion 204b. For example, the second inner portion 220i and/or the third inner portion 230i may include the conductive layer 204 and the inner layer 205 between the first and second insulation portions 202a and 202b in the intersection direction (e.g., the X-axis direction and/or the Y-axis direction). For example, as shown in (b) and (c) of FIG. 4, the conductive layer 204 may include first and second conductive portions 204a and 204b respectively on the opposing surfaces of the first and second insulation portions 202a and 202b, and the inner layer 205 may be between the first conductive portion 204a and the second conductive portion 204b in the intersection direction.

The filling conductive portion 204c, the first conductive portion 204a, and the second conductive portion 204b may be portions formed by the same process and including the same material. In some example embodiments, a thickness of the filling conductive portion 204c provided in the first portion 210 may be greater than a thickness of the first conductive portion 204a or the second conductive portion 204b of the second portion 220 or the third portion 230. For example, the thicknesses of the first conductive portions 204a and/or the second conductive portions 204b of the second portion 220 and the third portion 230 may be the same. However, the example embodiments are not limited thereto. In some example embodiments, the thickness of the filling conductive portion 204c of the first portion 210 may be equal to or smaller than the thickness of the first conductive portion 204a or the second conductive portion 204b of the second portion 220 or the third portion 230. In some example embodiments, the first conductive portions 204a and/or the second conductive portions 204b of the second and third portions 220 and 230 may include portions having different thicknesses.

The inner layer 205 of the second inner portion 220i and/or the third inner portion 230i may include the inner insulation layer 206 including an insulating material. In some example embodiments, the inner insulation layer 206 of the second inner portion 220i and/or the third inner portion 230i may include a first inner insulation portion 206a on the first conductive portion 204a and a second inner insulation portion 206b on the second conductive portion 204b. In some example embodiments, the space portion 208g may be between the first inner insulation portion 206a and the second inner insulation portion 206b in the second inner portion 220i and/or the third inner portion 230i. For example, as shown in (b) and (c) of FIG. 4, the inner layer 205 may include first and second inner insulation portions 206a and 206b respectively on the opposing surfaces of the first and second conductive portions 204a and 204b, and the inner layer 205 may include one or more inner surfaces (e.g., one or more inner surfaces 206s of the inner insulation layer 206 which may include opposing inner surfaces 206s of the first and second inner insulation portions 206a and 206b) that at least partially define a space portion 208g that may include an internal space between the first and second inner insulation portions 206a and 206b in the intersection direction.

In the second inner portion 220i and/or the third inner portion 230i, by positioning the inner insulation layer 206 on the first or second conductive portions 204a and 204b, the thickness of the first or second conductive portion 204a or 204b may be reduced and the structural stability of the pixel isolation portion 200 may be improved, thereby improving the reliability of the image sensor 100 due to reduced likelihood of defects due to structural deterioration. If the inner insulation layer 206 is not provided, the structural stability may be deteriorated if the conductive layer 204 has a thin thickness. In some example embodiments, there may be a limit to reducing the thickness of the first conductive portion 204a or the second conductive portion 204b by considering the structural stability.

In the second portion 220 and/or the third portion 230, the first inner insulation portion 206a and the second inner insulation portion 206b may be connected to the filling insulation portion 206c adjacent to the first surface 111 of the substrate 110.

In the thickness direction (the Z-axis direction of the drawing) of the substrate 110, a height of the space portion 208g of the second portion 220 may be less than a height of the second inner portion 220i. Here, the height of the space portion 208g may be the maximum length between the second surface 112 of the substrate 110 and the other end of the space portion 208g in the thickness direction of the substrate 110. That is, the second inner portion 220i may include a portion not having the space portion 208g (a portion of the second portion 220 illustrated in FIG. 5). In the portion of the second inner portion 220i, the first insulation portion 202a, the first conductive portion 204a, the filling insulation portion 206c, the second conductive portion 204b, and the second insulation portion 202b may be positioned. As shown, the space portion 208g may include an internal space that is at least partially defined by one or more inner surfaces 206s of the inner insulation layer 206, the end insulation portion 209, or the like. Accordingly, as shown in (b) of FIG. 4, the second inner portion 220i may include an inner insulation layer 206 that includes at least one of a first inner sub-portion p1 where the inner insulation layer 206 includes an insulating material (e.g., filling insulation portion 206c) that extends entirely between opposing surfaces 204s of the conductive layer 204 in the intersection direction or a second inner sub-portion p2 where the inner insulation layer 206 has inner surfaces 206s at least partially defining a space portion 208g having an internal space between opposing surfaces 204s of the conductive layer 204 (and in some example embodiments further between opposing inner surfaces 206s of the inner insulation layer 206) in the intersection direction. However, the example embodiments are not limited thereto, and the height of the space portion 208g of the second portion 220 in the thickness direction of the substrate 110 may be equal to or greater than the height of the second inner portion 220i.

In the thickness direction (the Z-axis direction of the drawing) of the substrate 110, a height of the space portion 208g of the third portion 230 may be smaller than a height of the third inner portion 230i. That is, the third inner portion 230i may include a portion not having the space portion 208g (a portion of the third portion 230 illustrated in FIG. 5). In the portion of the third inner portion 230i, the first insulation portion 202a, the first conductive portion 204a, the filling insulation portion 206c, the second conductive portion 204b, and the second insulation portion 202b may be positioned. As shown, the space portion 208g may include an internal space that is at least partially defined by one or more inner surfaces 206s of the inner insulation layer 206, the end insulation portion 209, or the like. Accordingly, as shown in (c) of FIG. 4, the third inner portion 230i may include an inner insulation layer 206 that includes at least one of a first inner sub-portion p1 where the inner insulation layer 206 includes an insulating material (e.g., filling insulation portion 206c) that extends entirely between opposing surfaces 204s of the conductive layer 204 in the intersection direction or a second inner sub-portion p2 where the inner insulation layer 206 has inner surfaces 206s at least partially defining a space portion 208g having an internal space between opposing surfaces 204s of the conductive layer 204 (and in some example embodiments further between opposing inner surfaces 206s of the inner insulation layer 206) in the intersection direction. However, the example embodiments are not limited thereto, and the height of the space portion 208g of the third portion 230 in the thickness direction of the substrate 110 may be equal to or greater than the height of the third inner portion 230i.

For example, in the thickness direction (the Z-axis direction of the drawing) of the substrate 110, the height of the space portion 208g of the third portion 230 may be greater than the height of the space portion 208g of the second portion 220. In the intersection direction that intersects the pixel isolation portion 200, a width of the space portion 208g of the third portion 230 may be greater than a width of the space portion 208g of the second portion 220. This is because the third portion 230 has the larger width and larger volume than the second portion 220 and thus the space portion 208g of the third portion 230 has the relatively larger depth, larger width, or larger volume. However, the example embodiments are not limited thereto. In the thickness direction of the substrate 110, the height of the space portion 208g of the third portion 230 may be equal to or less than the height of the space portion 208g of the second portion 220. In the intersection direction, the width of the space portion 208g of the third portion 230 may be equal to or less than the width of the space portion 208g of the second portion 220.

In some example embodiments, the space portion 208g, which has a lower refractive index than the conductive layer 204 or the inner insulation layer 206 and has an internal space or air gap, may be in the second inner portion 220i and/or the third inner portion 230i. The space portion 208g may be an internal space or air gap (e.g., an enclosure) that is at least partially defined by one or more inner surfaces of the inner insulation layer 206 and/or the end insulation portion 209. Accordingly, the inner layer 205 may have the lower refractive index than the conductive layer 204. Also, there is no need to add a separate process to fill the inside of the space portion 208g and thus a process time and a process cost may be reduced, thereby improving manufacturing cost efficiency to manufacture the image sensor 100.

For example, the filling insulation portion 206c, the first inner insulation portion 206a, and the second inner insulation portion 206b or the first portion 210, the second portion 220, or the third portion 230 may be portions formed through the same process and including the same material.

For example, the thickness of the filling insulation portion 2060 of the second portion 220 may be greater than the thickness of the filling insulation portion 206c of the first portion 210, and the thickness of the filling insulation portion 206c of the third portion 230 may be greater than the thickness of the filling insulation portion 206c of the second portion 220. This is because the second portion 220 has a larger width than the first portion 210, and the third portion 230 has a larger width than the second portion 220.

For example, the thickness of the filling insulation portion 206c of the first portion 210, the second portion 220, or the third portion 230 may be greater than the thickness of the first inner insulation portion 206a or the second inner insulation portion 206b of the second portion 220 or the third portion 230. For example, the thickness of the first inner insulation portions 206a and/or the second inner insulation portions 206b of the second portion 220 and the third portion 230 may be the same as each other. However, the example embodiments are not limited thereto. Therefore, the first inner insulation portions 206a and/or the second inner insulation portions 206b of the second and third portions 220 and 230 may include portions having different thicknesses.

The second portion 220 and/or the third portion 230 may have an electrical insulation structure between the first insulation portion 202a and the second insulation portion 202b by the inner layer 205. For example, in the second portion 220 and/or the third portion 230, the inner layer 205 may at least partially define an electrical insulation structure between the first and second insulation portions 202a and 202b such that the second portion 220 and/or the third portion 230 has an electrical insulation structure at least partially defined by the inner layer 205 (e.g., at least partially defined by the inner layer 205 between the first and second insulation portions 202a and 202b). The second portion 220 and/or the third portion 230 may have a total reflection structure between the first and second insulation portions 202a and 202b by the conductive layer 204 having the relatively high refractive index and the inner layer 205 having the relatively low refractive index. For example, in the second portion 220 and/or the third portion 230, the conductive layer 204 and the inner layer 205 may at least partially define a total reflection structure between the first and second insulation portions 202a and 202b such that the second portion 220 and/or the third portion 230 has a total reflection structure at least partially defined by the conductive layer 204 and the inner layer 205 (e.g., at least partially defined by the conductive layer 204 and the inner layer 205 between the first and second insulation portions 202a and 202b). Since the first conductive portion 204a or the second conductive portion 204b of the second portion 220 or the third portion 230 has the thin thickness, light may pass through the first conductive portion 204a or the second conductive portion 204b and be directed to the inner layer 205. The light directed to the inner layer 205 may be totally reflected and directed to the photoelectric converter 120, which may improve image sensing performance of the image sensor 100.

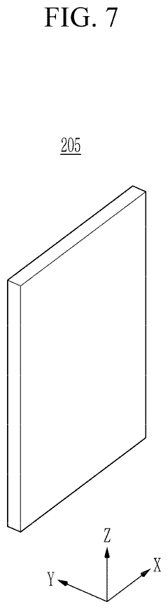

A shape of the inner layer 205 of the second portion 220 or the third portion 230 of the pixel isolation portion 200 will be described with reference to FIG. 7 along with FIG. 2 to FIG. 6.

FIG. 7 is a perspective view schematically illustrating an example of the inner layer 205 included in the second portion 220 or the third portion 230 of the pixel isolation portion 200 illustrated in FIG. 4 according to some example embodiments.

Referring to FIG. 2 to FIG. 7, in some example embodiments, the inner layer 205 may have a sheet shape having a plane extending in the extension direction of the pixel isolation portion 200 and the thickness direction of the substrate 110 and having a width in the intersecting direction intersecting the pixel isolation portion 200. For example, in the pixel isolation portion 200 that extends in the first direction (the X-axis direction of the drawing), the inner layer 205 may have a plane (a XZ plane of the drawing) that extends in the first direction and the thickness direction (the Z-axis direction of the drawing) and a width in the second direction (the Y-axis direction of the drawing) that intersects the first direction. For example, in the pixel isolation portion 200 that extends in the second direction, the inner layer 205 may have a plane (a YZ plane in the drawing) in the second direction and the thickness direction and have a width in the first direction.

In FIG. 7, it is illustrated an example that both lateral side surfaces of the inner layer 205 are vertical planes in a cross-section perpendicular to the extension direction of the pixel isolation portion 200. Then, the inner layer 205 may have a uniform thickness along the thickness direction (the Z-axis direction of the drawing) of the substrate 110, and the inner layer 205 may have a rectangular shape in a cross-section perpendicular to the extension direction of the pixel isolation portion 200. For example, the inner layer 205 may have a rectangular parallelepiped shape.

However, the example embodiments are not limited thereto. Therefore, in the cross-section perpendicular to the extension direction of the pixel isolation portion 200, both lateral side surfaces of the inner layer 205 may include a portion having an inclined surface. For example, the side surfaces of the inner layer 205 may be inclined surfaces so that a width of the inner layer decreases as the inner layer moves from the first surface 111 of the substrate 110 to the second surface 112 of the substrate. For example, the width of the inner layer 205 gradually decreases from the first surface 111 of the substrate 110 toward the second surface 112 and thus the inner layer 205 may have a trapezoid shape in the cross-section perpendicular to the extension direction of the pixel isolation portion 200.

As such, when the inner layer 205 has the sheet shape, the total reflection at the second portion 220 and the third portion 230 may be stable. On the other hand, if a void that is undesirably formed due to limitations in a manufacturing process, the void does not have a sheet shape and may have an irregular shape in a small region. In the void formed irregularly in the small regions, it is difficult for light to be totally reflected and light may be scattered. Accordingly, it is not suitable for reflecting light toward a photoelectric converter.

For example, the width of the inner layer 205 in the intersection direction intersecting the pixel isolation portion 200 may be 1 nm or more (e.g., 1 nm to 500 nm, etc.). If the width of the inner layer 205 is 1 nm or more, the total reflection structure may be stable. However, the example embodiments are not limited thereto, and the width of the inner layer 205 or the width of the space portion 208g may be less than 1 nm (e.g., 0.01 nm to 1 nm, 0.1 nm to 1 nm, 0.5 nm to 1 nm, etc.).

In the intersection direction intersecting the pixel isolation portion 200, the first inner portion 210i may include a portion in which the first insulation portion 202a, the filling conductive portion 204c, and the second insulation portion 202b are sequentially positioned. In the intersection direction intersecting the pixel isolation portion 200, the second inner portion 220i or the third inner portion 230i may include a portion in which the first insulation portion 202a, the first conductive portion 204a, the first inner insulation portion 206a, the space portion 208g, the second inner insulation portion 206b, the second conductive portion 204b, and the second insulation portion 202b are sequentially positioned.

In some example embodiments, first portions 210 may be at both sides (e.g., opposite sides) of the second portion 220. More particularly, the first portion 210 may be between the second portion 220 and the third portion 230 that are located at both sides, respectively. Accordingly, the second portion 220 may be at a center portion in the extension direction of the pixel isolation portion 200. Accordingly, the second portion 220, which has the total reflection structure, is positioned in the central portion to increase or maximize the amount of light reaching the photoelectric converter 120 by the reflection of light, thereby improving image sensing performance of the image sensor 100. However, the example embodiments are not limited thereto.

In the extension direction of the pixel isolation portion 200 (e.g., in the plan view as shown in FIG. 2), a length L1 of the first portion 210 may be smaller than a length L2 of the second portion 220. More particularly, in the extension direction of the pixel isolation portion 200, a total length of the first portion 210 or the first portions 210 may be smaller than the length L2 of the second portion 220. The length L1 of the first portion 210 may be relatively reduced and the length L2 of the second portion 220, which has the total reflection structure, may be sufficiently secured. As a result, the amount of light directing to the photoelectric converter 120 may be increased based on increasing the light reflection at the second portion 220, thereby improving image sensing performance of the image sensor 100. However, the example embodiments are not limited thereto, and the length L1 of the first portion 210 or the total length of the first portion 210 or the first portions 210 may be equal to or greater than the length L2 of the second portion 220.

In the extension direction of the pixel isolation portion 200 (e.g., in the plan view as shown in FIG. 2), a ratio (L2/L0) of the length L2 (e.g., a total length) of the second portion 220 to a length L0 of the pixel isolation portion 200 may be more than 50%. For example, in the extension direction of the pixel isolation portion 200, the ratio (L2/L0) of the length L2 (e.g., the total length) of the second portion 220 to the length L0 of the pixel isolation portion 200 may be 70% to 95%. The length L2 of the second portion 220 may be sufficiently secured. As a result, the amount of light directing to the photoelectric converter 120 may be increased based on increasing the light reflection at the second portion 220, thereby improving image sensing performance of the image sensor 100. However, the example embodiments are not limited thereto, and, in the extension direction of the pixel isolation portion 200, the ratio (L2/L0) of the length L2 (e.g., the total length) of the second portion 220 to the length L0 of the pixel isolation portion 200 may be less than 50%.

The first width W1 of the first portion 210 may be equal to or less than twice the thickness of the first or second insulation portion 202a or 202b, or a sum of the thickness of the first insulation portion 202a and the thickness of the second insulation portion 202b. The second width W2 of the second portion 220 may be greater than twice the thickness of the first or second insulation portion 202a or 202b, or the sum of the thickness of the first insulation portion 202a and the thickness of the second insulation portion 202b.

For example, a ratio (W2/W1) of the second width W2 of the second portion 220 to the first width W1 of the first portion 210 may be 1.05 to 3. For example, the ratio (W2/W1) of the second width W2 of the second portion 220 to the first width W1 of the first portion 210 may be 1.05 to 2. If the ratio (W2/W1) is less than 1.05, it may be difficult to form the different stacking structures of the first portion 210 and the second portion 220. If the above ratio (W2/W1) exceeds 3 (e.g., 2), the second width W2 of the second portion 220 may be greater than a certain level. However, the example embodiments are not limited thereto. For example, the ratio (W2/W1) of the second width W2 of the second portion 220 to the first width W1 of the first portion 210 may be less than 1.05 or may exceed 3.

In some example embodiments, the thickness T1 of the first or second insulation portion 202a or 202b may be greater than the thickness T2 of the first or second conductive portion 204a or 204b (e.g., at a common height level in the thickness direction (the Z-axis direction of the drawing)). The thickness T3 of the first or second inner insulation portion 206a or 206b may be greater than the thickness T2 of the first or second conductive portion 204a or 204b (e.g., at a common height level in the thickness direction (the Z-axis direction of the drawing)). In some example embodiments, the thickness of the inner layer 205 (e.g., in the intersection direction) may be greater than the thickness T2 of the first or second conductive portion 204a or 204b (e.g., in the intersection direction). In the second portion 220 and/or the third portion 230, the light absorption by the conductive layer 204 may be reduced or minimized by reducing the thickness T2 of the first or second conductive portion 204a or 204b, or the thickness of the conductive layer 204.

However, the example embodiments are not limited thereto. Therefore, the thickness T1 of the first or second insulation portion 202a or 202b may be equal to or smaller than the thickness T2 of the first or second conductive portion 204a or 204b. In some example embodiments, the thickness T3 of the first or second inner insulation portion 206a or 206b may be equal to or smaller than the thickness T2 of the first or second conductive portion 204a or 204b. In some example embodiments, the thickness of the inner layer 205 may be equal to or smaller than the thickness T2 of the first or second conductive portion 204a or 204b.

As in the above, the conductive layer 204 of the pixel isolation portion 200 may include or be composed of a semiconductor layer including a dopant. In some example embodiments, the conductive layer 204 of the pixel isolation portion 200 might not include a semiconductor layer not including a dopant.

In some example embodiments, the amount of light absorbed in the conductive layer 204 may be reduced by reducing the thickness of the conductive layer 204, which may absorb a relatively large amount of light in the pixel isolation portion 200. Accordingly, a quantum efficiency (QE) may be improved by increasing the amount of light reaching the photoelectric converter 120, thereby improving image sensing performance of the image sensor 100. Also, in the pixel isolation portion 200, the process of forming the semiconductor layer not including the dopant may be omitted, thereby simplifying the process for manufacturing the image sensor 100.

In some example embodiments, the pixel isolation portion 200 between the first pixel region PX1 and the second pixel region PX2 may include the first portion 210, the second portion 220, and/or the third portion 230 having the different widths and the different stacking structures. That is, a part (e.g., the first portion 210) of the pixel isolation portion 200 may be a portion that has an electrical connection structure by the filling conductive portion 204c, and another part (e.g., the second portion 220 and/or the third portion 230) of the pixel isolation portion 200 may be a portion in which the total reflection is induced by the conductive layer 204 and the inner layer 205. Accordingly, the dark current may be reduced, the crosstalk may be reduced, and a modulation transfer function (MTF) or a resolution may be improved.

Accordingly, performance of the image sensor 100 (e.g., image sensing performance) may be improved. It will be understood that improvements in the performance of the image sensor 100 may include improved power consumption efficiency of the image sensor 100, including for example improved image sensing performance of the image sensor 100 without increase in power consumption by the image sensor 100 and/or reduced power consumption by the image sensor 100 without compromising image sensing performance of the image sensor 100.

The image sensor 100 according to some example embodiments may be an infrared image sensor capable of detecting an optical depth information of an object using infrared light. Accordingly, the color filter 160 may include an infrared filter for passing infrared light, or the pixel region PX may include an infrared pixel that detects an optical depth information from an infrared wavelength. When the pixel isolation portion 200 according to some example embodiments is applied to an infrared image sensor, infrared light that has a large wavelength and has a large amount of light that escapes without being absorbed by the photoelectric converter 120 be used more effectively.

FIG. 3 illustrates that the dummy pixel isolation portion 200d has the same structure and shape as the first portion 210, but the example embodiments are not limited thereto. The dummy pixel isolation portion 200d may have a structure or shape of the second portion 220 or the third portion 230, or may be a structure or shape different form a structure of the second portion 220 or the third portion 230.

A manufacturing method of the image sensor 100 will be explained in more detail with reference to FIG. 8A to FIG. 8H.

FIGS. 8A, 8B, 8C, 8D, 8E, 8F, 8G, and 8H are cross-sectional views illustrating a manufacturing method of an image sensor according to some example embodiments. FIG. 8A to FIG. 8H illustrate a portion corresponding to FIG. 3. To the extent that an element is not described in detail below, it may be understood that the element is at least similar to a corresponding element that has been described elsewhere within the present inventive concepts. A portion which is not described in the above will be described in detail.

As illustrated in FIG. 8A, a first trench 300a may be formed at a first surface 111 of a substrate 110 having the first surface 111 and a preliminary surface 112p facing each other.

More particularly, a mask pattern 310 having an opening 310a exposing a region corresponding to a device isolation portion 300 may be formed on the first surface 111 of the substrate 110. The mask pattern 310 may include various insulating materials, for example, silicon nitride. The first trench 300a may be formed by etching a portion of the substrate 110 exposed through an opening 310a of the mask pattern 310. As an etching process, various processes such as a wet etching process or a dry etching process may be used.

Subsequently, as illustrated in FIG. 8B, a preliminary device isolation portion 300p and a second trench 200a may be formed at the first surface 111 side of the substrate 110.

More particularly, the preliminary device isolation portion 300p may be formed at the first surface 111 of the substrate 110. In some example embodiments, the preliminary device isolation portion 300p may fill the first trench 300a. A portion of the substrate 110 may be etched to form the second trench 200a. In some example embodiments, the preliminary device isolation portion 300p may be used as a mask pattern, or a separate mask pattern may be used. As an etching process, various processes such as a wet etching process or a dry etching process may be used.

In some example embodiments, the second trench 200a may be formed to have sizes respectively corresponding to a first portion 210 (refer to FIG. 8C), a second portion 220 (refer to FIG. 8C), and the third portion 230 (refer to FIG. 8C) of the pixel isolation portion 200. That is, the second trench 200a corresponding to the second portion 220 may have a larger width than the second trench 200a corresponding to the first portion 210, and the second trench 200a corresponding to the third portion 230 may have a larger width than the second trench 200a corresponding to the second portion 220.

Subsequently, as illustrated in FIG. 80, an insulation layer 202, a conductive layer 204, and an inner insulation layer 206 are sequentially formed at an inside of the second trench 200a, and the mask pattern 310 (refer to FIG. 8B) and portions of the preliminary device isolation portion 300p (refer to FIG. 8B), the insulation layer 202, and the inner insulation layer 206 on the first surface 111 of the substrate 110 may be removed.

More particularly, the insulation layer 202 may be formed to have a uniform thickness on an inner surface of the second trench 200a. In some example embodiments, in the first portion 210, the second portion 220, and the third portion 230, the insulation layer 202 may be formed entirely on the inner surface and a bottom surface of the second trench 200a. In addition, the insulation layer 202 may be entirely formed on the first surface 111 of the substrate 110. The insulation layer 202 may include a first insulation portion 202a and a second insulation portion 202b.

Subsequently, a conductive layer 204 may be formed on the insulation layer 202 at an inside of the second trench 200a. In the first portion 210, which has a relatively small width, the conductive layers 204 formed on the inner surfaces at both sides of the second trench 200a may be in contact with each other and be positioned entirely inside the first portion 210. Accordingly, in the first portion 210, the conductive layer 204 may include or be composed of a single filling conductive portion 204c that fills an inside of the insulation layer 202. In the second portion 220 or the third portion 230, which has a relatively large width, the conductive layers 204 formed on the inner surfaces at both sides of the second trench 200a may be spaced apart from each other (e.g., isolated from direct contact with each other). Accordingly, in the second portion 220 and the third portion 230, the conductive layer 204 may include a first conductive portion 204a and a second conductive portion 204b on the inner surfaces of both sides, respectively.

In some example embodiments, the conductive layer 204 may be positioned on the inner side surface or the inner side surfaces at portions corresponding to first to third inner portions 210i, 220i, and 230i (refer to FIG. 4) in the second trench 200a, and might not be positioned at portions corresponding to first to third isolation portions 210j, 220j, and 230j (refer to FIG. 4). The conductive layer 204 may be formed and then a partial portion of the conductive layer 204 may be removed to form the above structure, or the conductive layer 204 may be formed with a pattern to form the above structure.

Subsequently, an inner insulation layer 206 may be formed at the inside of the second trench 200a. In the first portion 210, the inner insulation layer 206 may include a filling insulation portion 206c at the first isolation portion 210j. In the second portion 220, the inner insulation layer 206 may include a filling insulation portion 206c in the second isolation portion 220j, and a portion on the conductive layer 204 in the second inner portion 220i. In the third portion 230, the inner insulation layer 206 may include a filling insulation portion 206c in the third isolation portion 230j, and a portion on the conductive layer 204 in the third inner portion 230i.

In the second inner portion 220i and/or the third inner portion 230i, the inner insulation layer 206 may be formed entirely on the inner side surface and the bottom surface of the second trench 200a on the conductive layer 204. In some example embodiments, in the second inner portion 220i and/or the third inner portion 230i, the inner insulation layer 206 may include first and second inner insulation portions 206a and 206b respectively on the first and second conductive portions 204a and 204b. In addition, the inner insulation layer 206 may be entirely on the first surface 111 of the substrate 110 on the insulation layer 202.

In some example embodiments, a space portion 208g may be between the first and second inner insulation portions 206a and 206b at the inside of the second inner portion 220i or the third inner portion 230i.

Subsequently, the mask pattern 310, and portions of the preliminary device isolation portion 300p, the insulation layer 202, and the inner insulation layer 206 on the first surface 111 of the substrate 110 may be removed. For example, a chemical mechanical polishing (CMP) process, a wet etching process, etc. may be used as a remove process. Thereby, a device isolation portion 300 and a pixel isolation portion 200 may be formed.

Subsequently, as illustrated in FIG. 8D, a photoelectric converter 120 may be formed, and a pixel circuit 130 and a wiring portion 140 may be formed.

More particularly, a second conductivity type dopant opposite to a first conductivity type dopant may be doped or injected from the first surface 111 of the substrate 110 toward the second surface 112 of the substrate 110 using a high energy implant method. Then, the photoelectric converter 120 corresponding to each pixel region PX by the device isolation portion 300 and/or the pixel isolation portion 200 may be formed. However, the process of forming the photoelectric converter 120 may be modified in various ways.

Subsequently, the pixel circuit 130 and the wiring portion 140 may be formed on the first surface 111 of the substrate 110. Various processes may be applied as the process for forming the pixel circuit 130 and the wiring portion 140.

Subsequently, as illustrated in FIG. 8E, a partial portion of the substrate 110 at the preliminary surface 112p (refer to FIG. 8D) of the substrate 110 (refer to FIG. 8E) may be removed. For example, the partial portion of the substrate 110 may be removed by performing a grinding process, a polishing process, a grinding process, an etching process, etc. at the preliminary surface 112p of the substrate 110. For example, the partial portion of the substrate 110 may be removed so that the pixel isolation portion 200 is at the second surface 112 of the substrate 110.

In some example embodiments, as illustrated in an enlarged view of FIG. 8E, the space portions 208g of the second portion 220 and the third portion 230 may be opened at a side of the second surface 112. For simple illustration and a clear understanding, in the enlarged view of FIG. 8E, the second portion 220 and the third portion 230, which have the same stacking structure, are illustrated together, but the second portion 220 and the third portion 230 may have different widths or sizes.

Next, as illustrated in FIG. 8F and FIG. 8G, an end insulation portion 209 at one end of the space portion 208g may be formed. For simple illustration and a clear understanding, in enlarged views of FIG. 8F and FIG. 8G, the second portion 220 and the third portion 230, which have the same stacking structure, are illustrated together, but the second portion 220 and the third portion 230 may have different widths or sizes.

More particularly, as illustrated in FIG. 8F, a preliminary end insulation layer 209p may be formed on the second surface 112 of the substrate 110. The preliminary end insulation layer 209p may be partially formed at an inside of the space portion 208g. In some example embodiments, the preliminary end insulation layer 209p may be partially formed at one end of the space portion 208g adjacent to the second surface 112 of the substrate 110 by using a process method, a process speed, etc. that does not completely fill the inside of the space portion 208g.

Subsequently, as illustrated in FIG. 8G, a partial portion of the preliminary end insulation layer 209p (refer to FIG. 8F) on the second surface 112 of the substrate 110 may be removed. For example, a chemical mechanical polishing process, a wet etching process, or so on may be used as a remove process. As a result, the end insulation portion 209 may be formed.

Next, as illustrated in FIG. 8H, a contact portion 180, a horizontal insulation layer 150, a color filter 160, a filter isolation portion 162, and a micro lens 170 may be formed. Various processes may be applied to processes of forming the contact portion 180, the horizontal insulation layer 150, the color filter 160, the filter isolation portion 162, and the micro lens 170.

According to some example embodiments, the pixel isolation portion 200 including the first portion 210, the second portion 220, and/or the third portion 230 with different stacking structures may be formed by a width difference between the first portion 210, the second portion 220, and/or the third portion 230, without adding a separate process. That is, the image sensor 100 with enhanced performance may be formed through an easy manufacturing process, thereby reducing manufacturing costs and/or reducing complexity of the manufacturing process, which may result in reduced likelihood of process defects in the manufactured image sensor 100 and thus result in improved reliability of such manufactured image sensor 100.

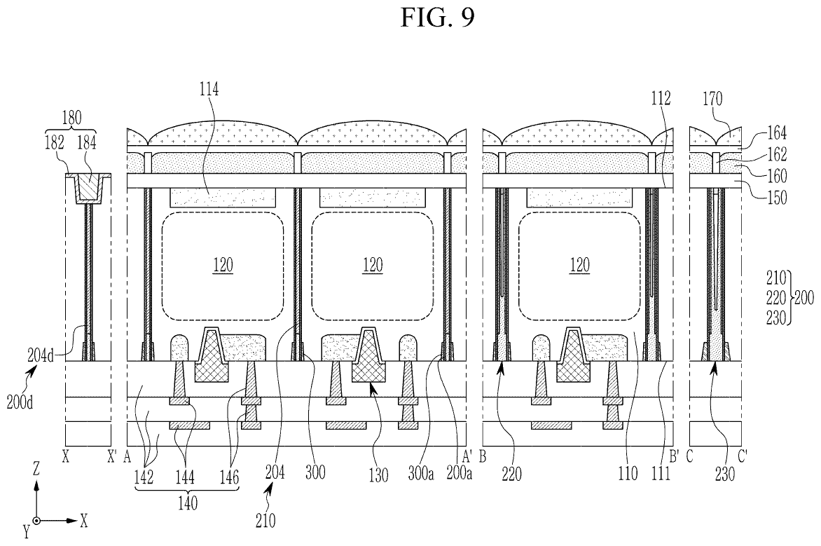

Hereinafter, an image sensor and a manufacturing method according to some example embodiments different from the above-described example embodiments (e.g., the example embodiments described with regard to FIGS. 2-7) is described in detail with reference to FIG. 9 to FIG. 13. To the extent that an element is not described in detail below, it may be understood that the element is at least similar to a corresponding element that has been described elsewhere within the present inventive concepts. A portion which is not described in the above will be described in detail.

FIG. 9 is a cross-sectional view of an image sensor according to some example embodiments. FIG. 9 illustrates a portion corresponding to FIG. 3. For simple illustration and a clear understanding, in FIG. 9, a light scattering pattern 114 is conceptually illustrated.

Referring to FIG. 9, in an image sensor according to some example embodiments, a light scattering pattern 114 may be at a position adjacent to a second surface 112 of a substrate 110 (e.g., on a portion or part that is adjacent to the second surface 112). A surface of the light scattering pattern 114 may be on the same plane as (e.g., coplanar with) the second surface 112 of the substrate 110. The light scattering pattern 114 may have any of various planar shapes such as circular, polygon, and cross shapes, and the example embodiments are not limited to the planar shape of the light scattering pattern 114. FIG. 9 illustrates that light scattering pattern 114 has a constant thickness to easily form the light scattering pattern 114 through an easy manufacturing process to manufacture the image sensor comprising the light scattering pattern 114, thereby reducing manufacturing costs and/or reducing complexity of the manufacturing process, which may result in reduced likelihood of process defects in the manufactured image sensor and thus result in improved reliability of such manufactured image sensor. However, the example embodiments are not limited thereto, and the light scattering pattern 114 may include portions having different thicknesses.

The light scattering pattern 114 may be formed by removing a partial portion of the substrate 110 and then filling the removed portion with an insulating material. For example, the light scattering pattern 114 may include or be made of a high dielectric constant insulating material that has a higher dielectric constant than silicon oxide. As an example, the light scattering pattern 114 may include a metal oxide or a metal fluoride including at least one of hafnium, zirconium, aluminum, tantalum, titanium, or yttrium. According to this, dark current may be improved (e.g., reduced) by a hole accumulation at a periphery of the light scattering pattern 114, thereby improving image sensing performance of the image sensor.

The light scattering pattern 114 may increase a light path by scattering long wavelength light. In some example embodiments, the image sensor according to some example embodiments may be an infrared image sensor. For example, the light scattering pattern 114 may increase the light path by scattering infrared light. When the infrared image sensor includes the light scattering pattern 114, an amount of infrared light reaching a photoelectric converter 120 may be increased, thereby improving image sensing performance of the image sensor.

When the pixel isolation portion 200 including a first portion 210, a second portion 220, and a third portion 230 is applied to the image sensor including the light scattering pattern 114, the light scattered by the light scattering pattern 114 and directing toward the pixel isolation portion 200 may be totally reflected in the second portion 220 and/or the third portion 230 and absorbed more into the photoelectric converter 120.

That is, in some example embodiments, the pixel isolation portion 200 including the first, second, and third portions 210, 220, and 230 may be applied to the infrared image sensor using infrared rays and including the light scattering pattern 114. Then, a crosstalk or a resolution between pixel regions PX may be improved more.

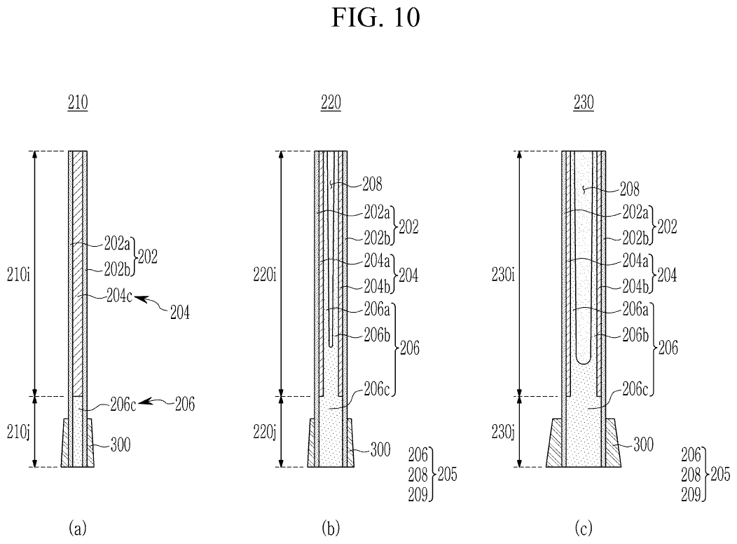

FIG. 10 is a cross-sectional view illustrating a pixel isolation portion included in an image sensor according to some example embodiments. FIG. 10 illustrates a portion corresponding to FIG. 4.

Referring to FIG. 10, in an image sensor according to some example embodiments, an inner layer 205 may include an inner insulation layer 206 and an additional inner insulation layer 208.

More particularly, in a second inner portion 220i, a conductive layer 204 may include a first conductive portion 204a and a second conductive portion 204b respectively on a first insulation portion 202a and a second insulation portion 202b. In the second inner portion 220i, an inner layer 205 may include a first inner insulation portion 206a and a second inner insulation portion 206b respectively on the first conductive portion 204a and the second conductive portion 204b, and an additional inner insulation layer 208 between the first inner insulation portion 206a and the second inner insulation portion 206b (e.g., between the first inner insulation portion 206a and the second inner insulation portion 206b in the intersection direction).

In a third inner portion 230i, the conductive layer 204 may include the first conductive portion 204a and the second conductive portion 204b respectively on the first insulation portion 202a and the second insulation portion 202b. In the third inner portion 230i, the inner layer 205 may include the first inner insulation portion 206a and the second inner insulation portion 206b respectively on the first conductive portion 204a and the second conductive portion 204b, and the additional inner insulation layer 208 between the first inner insulation portion 206a and the second inner insulation portion 206b.

In some example embodiments, the conductive layer 204 may include a polycrystalline semiconductor including a dopant, and the additional inner insulation layer 208 may have a refractive index less than a refractive index of the conductive layer 204. For example, the refractive index of the additional inner insulation layer 208 may be 4.0 or less. For example, the additional inner insulation layer 208 may include various insulating materials such as oxide, nitride, oxynitride, or fluoride. For example, the additional inner insulation layer 208 may include at least one of silicon oxide, silicon nitride, aluminum oxide, or hafnium oxide. However, the example embodiments are not limited to the material of the additional inner insulation layer 208.

The additional inner insulation layer 208 may include or be made of the same material as the inner insulation layer 206 or may include or be made of a different material from the inner insulation layer 206. When the additional inner insulation layer 208 and the inner insulation layer 206 include the same material, a boundary between the additional inner insulation layer 208 and the inner insulation layer 206 may be confirmed or might not be confirmed.

The description of the manufacturing method referring to FIG. 8A to FIG. 8H may be applied as it is to a manufacturing method of the image sensor illustrated in FIG. 10 except for differences later described. In the manufacturing method of the image sensor illustrated in FIG. 10, an insulation layer 202, a conductive layer 204, and an inner insulation layer 206 may be formed at an inside of a second trench 200a (refer to FIG. 8B) in the process corresponding to FIG. 8C, and then, the additional inner insulation layer 208 may be formed at an inside of the inner insulation layer 206 in the second portion 220 and the third portion 230. Subsequently, a mask pattern 310, a second mask pattern, the insulation layer 202, the inner insulation layer 206, and the additional inner insulation layer 208 on a first surface 111 of a substrate 110 may be removed. Subsequently, a forming process of an end insulation portion 209 referring to FIG. 8F and FIG. 8G might not be performed.

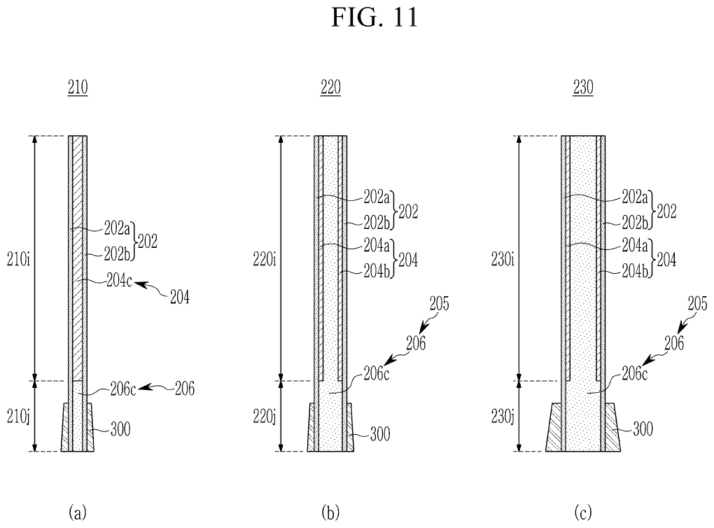

FIG. 11 is a cross-sectional view of an image sensor according to some example embodiments. FIG. 11 illustrates a portion corresponding to FIG. 4.

Referring to FIG. 11, in an image sensor according to some example embodiments, an inner layer 205 may include an inner insulation layer 206.

More particularly, in a second inner portion 220i, a conductive layer 204 may include a first conductive portion 204a and a second conductive portion 204b respectively on a first insulation portion 202a and a second insulation portion 202b. In the second inner portion 220i, the inner layer 205 may include a filling insulation portion 206c between the first conductive portion 204a and the second conductive portion 204b. For example, in the second inner portion 220i, the inner layer 205 may include a filling insulation portion 206c that fills (e.g., occupies) a space defined between the first conductive portion 204a and the second conductive portion 204b in the intersection direction. For example, the filling insulation portion 206c may extend entirely between the first conductive portion 204a and the second conductive portion 204b in the intersection direction. In some example embodiments, there may be a partial portion where the inner insulation layer 206 or the filling insulation portion 206c is not positioned between the first conductive portion 204a and the second conductive portion 204b.

In a third inner portion 230i, the conductive layer 204 may include the first conductive portion 204a and the second conductive portion 204b respectively on the first insulation portion 202a and the second insulation portion 202b. In the third inner portion 230i, the inner layer 205 may include a filling insulation portion 206c between the first conductive portion 204a and the second conductive portion 204b. For example, in the third inner portion 230i, the inner layer 205 may include a filling insulation portion 206c that fills (e.g., occupies) a space defined between the first conductive portion 204a and the second conductive portion 204b in the intersection direction. For example, the filling insulation portion 206c may extend entirely between the first conductive portion 204a and the second conductive portion 204b in the intersection direction. In some example embodiments, there may be a partial portion where the inner insulation layer 206 or the filling insulation portion 206c is not positioned between the first conductive portion 204a and the second conductive portion 204b.

The description of the manufacturing method referring to FIG. 8A to FIG. 8H may be applied as it is to a manufacturing method of the image sensor illustrated in FIG. 11 except for differences described later. In the manufacturing method of the image sensor illustrated in FIG. 11, in the process corresponding to FIG. 8C (that is, in the process of sequentially forming the insulation layer 202, the conductive layer 204, and the inner insulation layer 206 at an inside of a second trench 200a (refer to FIG. 8B)), the inner insulation layer 206 may be formed to fill an inside of the conductive layer 204. Subsequently, a forming process of an end insulation portion 209 referring to FIG. 8F and FIG. 8G might not be performed.

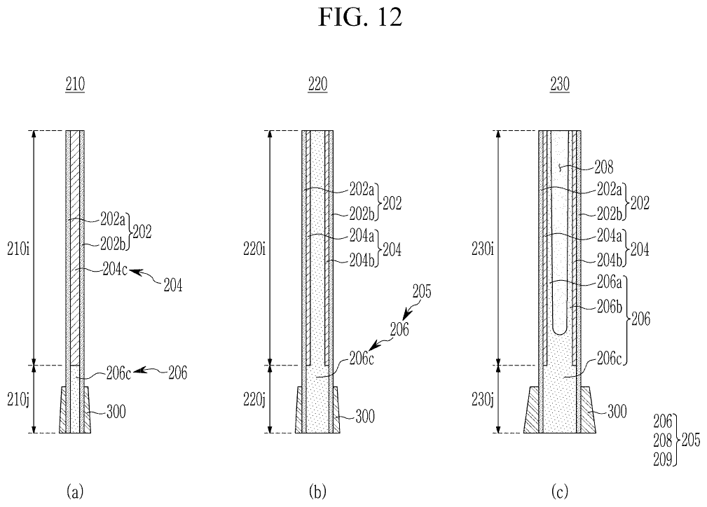

FIG. 12 is a cross-sectional view illustrating a pixel isolation portion included in an image sensor according to some example embodiments. FIG. 12 illustrates a portion corresponding to FIG. 4.

Referring to FIG. 12, in an image sensor according to some example embodiments, an inner layer 205 of a second portion 220 and the inner layer 205 of the third portion 230 may have different stacking structures.

More particularly, in the second inner portion 220i, a conductive layer 204 may include a first conductive portion 204a and a second conductive portion 204b on a first insulation portion 202a and a second insulation portion 202b, respectively. In the second inner portion 220i, the inner layer 205 may include a filling insulation portion 206c between the first conductive portion 204a and the second conductive portion 204b.

In the third inner portion 230i, the conductive layer 204 may include the first conductive portion 204a and the second conductive portion 204b respectively on the first insulation portion 202a and the second insulation portion 202b. In the third inner portion 230i, the inner layer 205 may include a first inner insulation portion 206a and a second inner insulation portion 206b respectively on the first conductive portion 204a and the second conductive portion 204b, and an additional inner insulation layer 208 between the first inner insulation portion 206a and the second inner insulation portion 206b.

As shown in FIG. 12, the second portion 220 and/or the third portion 230 may include an inner layer 205 that includes at least one of an inner insulation layer 206 that includes an insulating material (e.g., a filling insulation portion 206c) that extends entirely between opposing surfaces of the conductive layer 204 in the intersection direction (e.g., in the second inner portion 220i) or may include an inner layer 205 that includes an inner insulation layer 206 and an additional inner insulation layer 208 in the intersection direction (e.g., in the third inner portion 230i).

The description of the manufacturing method referring to FIG. 8A to FIG. 8H may be applied as it is to a manufacturing method of the image sensor illustrated in FIG. 12 except for differences described later.

In the manufacturing method of the image sensor illustrated in FIG. 12, a process corresponding to FIG. 8C is as follows. In the process of sequentially forming the insulation layer 202, the conductive layer 204, and the inner insulation layer 206 at an inside of a second trench 200a (refer to FIG. 8B), the inner insulation layer 206 may be formed to fill an inside of the conductive layer 204 in the second portion 220. In the third portion 230, the additional inner insulation layer 208 may be formed at an inside of the inner insulation layer 206. A mask pattern 310, a second mask pattern, the insulation layer 202, the inner insulation layer 206, and the additional inner insulation layer 208 on a first surface 111 of a substrate 110 may be removed. Subsequently, a forming process of an end insulation portion 209 referring to FIG. 8F and FIG. 8G might not be performed.

When forming the additional inner insulation layer 208, by the width difference of the second portion 220 and the third portion 230, the inner insulation layer 206 may be formed by entirely filling the inside of the conductive layer 204 of the second portion 220, but the inner insulation layer 206 might not entirely fill the inside of the conductive layer 204 of the third portion 230. In some example embodiments, as described above, the additional inner insulation layer 208 may be formed at the inside of the inner insulation layer 206 in the third portion 230.

As another example, as illustrated in (c) of FIG. 4, a space portion 208g and an end insulation portion 209 may be at an inside of the third portion 230. In addition, various structures in which the second portion 220 and third portion 230 have different stacking structures may be applied.

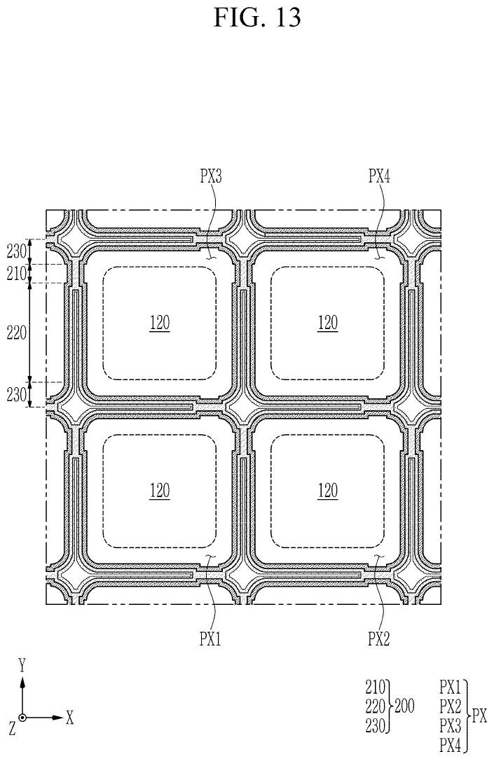

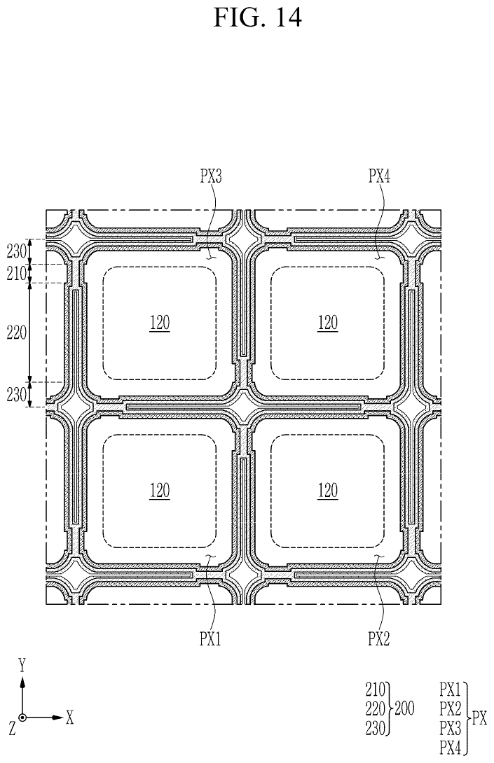

FIG. 13 and FIG. 14 are plan views of an image sensor according to some example embodiments. FIG. 13 and FIG. 14 illustrate a portion corresponding to FIG. 6.

Referring to FIG. 13 and FIG. 14, in some example embodiments, one first portion 210 may be in each pixel isolation portion 200. More particularly, the first portion 210 may be positioned between a second portion 220 and a third portion 230 at one side thereof, and the second portion 220 may be extended to another third portion 230. Accordingly, the second portion 220 may be at a center portion and one edge portion in an extension direction of the pixel isolation portion 200, while, as viewed in the plan view as shown in FIGS. 13 and 14, the first portion 210 may be at another edge portion of the pixel isolation portion 200. The second portion 220 and the third portion 230, which have a total reflection structure, may be connected at one edge portion. Accordingly, the second portion 220, which has a total reflection structure, is at the central portion and one edge portion to maximize an amount of light reaching the photoelectric converter 120 by the light reflection.

In some example embodiments, as illustrated in FIG. 13, with reference to each third portion 230, a second portion 220 of one pixel isolation portion 200 extending in a first direction (an X-axis direction of the drawing) and another second portion 220 of another pixel isolation portion 200 extending in a second direction (a Y-axis direction of the drawing) may be positioned to be adjacent to the third portion 230. As a result, an inner layer 205 in the second portion 220 and third portion 230 of the one pixel isolation portion 200 extending in the first direction, and the inner layer 205 in the second portion 220 of the another pixel isolation portion 200 extending in the second direction are connected continuously, thereby a total reflection by the inner layer 205 may be increased or maximized, thereby improving image sensing performance of the image sensor.

In some example embodiments, as illustrated in FIG. 14, with reference to each third portion 230, second portions 220 in two pixel isolation portions 200 extending in a first direction (an X-axis direction of the drawing) at both sides of the corresponding third portion 230 may be adjacent to the corresponding third portion 230. With reference to each third portion 230, first portions 210 in two pixel isolation portions 200 extending in a second direction (a Y-axis direction of the drawing) at both sides of the corresponding third portion 230 may be adjacent to the corresponding third portion 230. In some example embodiments, with reference to each third portion 230, first portions 210 in two pixel isolation portion 200 extending in the first direction (the X-axis direction of the drawing) at both sides of the corresponding third portion 230 may be adjacent to the corresponding third portion 230, and second portions 220 in two pixel isolation portions 200 extending in the second direction (the Y-axis direction of the drawing) at both sides of the corresponding third portion 230 may be adjacent to the corresponding third portion 230. Accordingly, the first portion 210 may be distributed more uniformly in each pixel region PX, thereby improving a stability of an electrical connection structure, thereby improving image sensing performance of the image sensor and/or improving the reliability of the image sensor based on reducing the likelihood of defects due to structural deterioration.

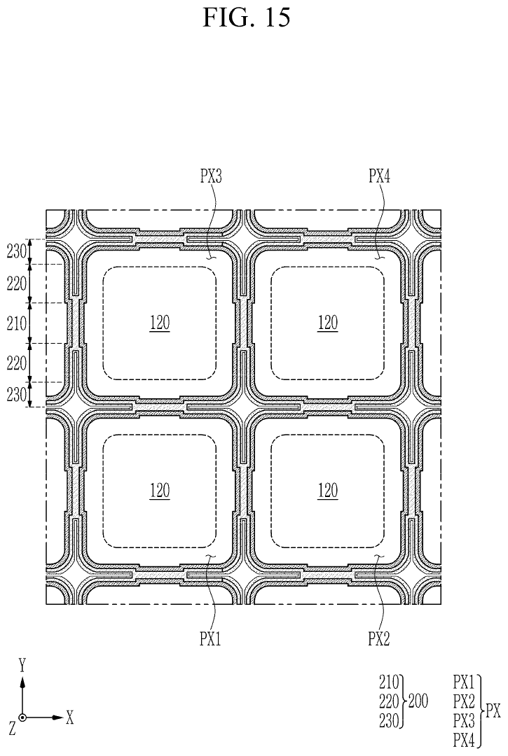

FIG. 15 is a plan view of an image sensor according to some example embodiments. FIG. 15 illustrates a portion corresponding to FIG. 6.

Referring to FIG. 15, in some example embodiments, a first portion 210 may be at a central portion of each pixel isolation portion 200 (e.g., when viewed in the plan view as shown in FIG. 15). In the drawing, it is illustrated that one first portion 210 is at the center portion, but the example embodiments are not limited thereto. In some example embodiments, the first portion 210 may be at the central portion of the pixel isolation portion 200 and provided in a plural in each pixel isolation portion 200. In addition, a position and number of the first portion 210 may be modified in various ways.

In FIG. 13 to FIG. 15, it is illustrated that the first portion 210, the second portion 220, and the third portion 230 have a structure illustrated in FIG. 6. However, the example embodiments are not limited thereto, and the structures of the first portion 210, the second portion 220, and the third portion 230 in some example embodiments, including the example embodiments shown in FIG. 10 to FIG. 12 may be applied to the first portion 210, the second portion 220, and the third portion 230 of some example embodiments, including the example embodiments shown in FIG. 13 to FIG. 15. Other various modifications are possible.

While the present example embodiments have been described in connection with what is presently considered to be practical example embodiments, it is to be understood that the present inventive concepts are not limited to such example embodiments. On the contrary, the present inventive concepts are intended to cover various modifications and equivalent arrangements included within the spirit and scope of the appended claims.

What is claimed is:

1. An image sensor, comprising:
a substrate including a plurality of pixel regions including a first pixel region and a second pixel region adjacent to each other;
a photoelectric converter at the substrate; and
a pixel isolation portion that separates the first pixel region and the second pixel region based on penetrating at least a part of the substrate between the first pixel region and the second pixel region,
wherein the pixel isolation portion includes first and second insulation portions respectively adjacent to the first and second pixel regions, and a conductive layer and an inner layer between the first and second insulation portions,
wherein the conductive layer and the inner layer include different materials, and
wherein the pixel isolation portion includes
a first portion including a portion where the conductive layer occupies a space defined between the first and second insulation portions in an intersection direction that intersects an extension direction of the pixel isolation portion, and
a second portion including the conductive layer and the inner layer between the first and second insulation portions in the intersection direction.

2. The image sensor of claim 1, wherein:
the inner layer has a refractive index less than a refractive index of the conductive layer, and
the inner layer includes an inner insulation layer including at least one of
an insulating material, or
inner surfaces at least partially defining a space portion that has an internal space between opposing surfaces of the conductive layer in the intersection direction.

3. The image sensor of claim 1, wherein:
in the second portion, the conductive layer includes first and second conductive portions respectively on the first and second insulation portions, and the inner layer is between the first conductive portion and the second conductive portion in the intersection direction.

4. The image sensor of claim 3, wherein:
in the second portion, the inner layer includes first and second inner insulation portions respectively on the first and second conductive portions, and one or more inner surfaces at least partially defining a space portion between the first and second inner insulation portions in the intersection direction.

5. The image sensor of claim 4, wherein:
in the second portion, the inner layer includes an end insulation portion at least partially defining one end of the space portion.

6. The image sensor of claim 3, wherein:
in the second portion, the inner layer includes first and second inner insulation portions respectively on the first and second conductive portions, and an additional inner insulation layer between the first and second inner insulation portions.

7. The image sensor of claim 3, wherein:
in the second portion, the inner layer includes a filling insulation portion that occupies a space defined between the first and second conductive portions in the intersection direction.

8. The image sensor of claim 3, wherein:
a thickness of the first conductive portion or the second conductive portion is less than a thickness of the first insulation portion or the second insulation portion, or
the thickness of the first conductive portion or the second conductive portion is less than a thickness of the inner layer.

9. The image sensor of claim 1, wherein:
a width of the second portion is larger than a width of the first portion.

10. The image sensor of claim 1, wherein:
when viewed in a plan view, a total length of the second portion is longer than a total length of the first portion, or
when viewed in a plan view, a ratio of the total length of the second portion to a length of the pixel isolation portion is greater than 50%.

11. The image sensor of claim 1, wherein:
when viewed in a plan view, the first portion is at an edge portion or a central portion of the pixel isolation portion.

12. The image sensor of claim 1, wherein:
the pixel isolation portion further includes a third portion including the conductive layer and the inner layer between the first and second insulation portions in the intersection direction and having a width greater than a width of the second portion.

13. The image sensor of claim 12, wherein:
the first pixel region and the second pixel region are adjacent in a first direction,
the image sensor further includes a third pixel region and a fourth pixel region respectively adjacent to the first pixel region and the second pixel region in a second direction crossing the first direction, and
the third portion is at a portion where the first to fourth pixel regions are adjacent to each other.

14. The image sensor of claim 1, wherein:
the conductive layer includes a polycrystalline semiconductor including a dopant, and
the inner layer includes at least one of oxide, nitride, oxynitride, fluoride, or one or more inner surfaces defining a space portion having an internal space.

15. An image sensor, comprising:
a substrate including a plurality of pixel regions;
a photoelectric converter at the substrate;
a light scattering pattern at a position adjacent to one surface of the substrate; and
a pixel isolation portion that separates the plurality of pixel regions based on penetrating at least a part of the substrate between the plurality of pixel regions,
wherein the pixel isolation portion includes a first portion and a second portion, the second portion having a width greater than a width of the first portion in an intersection direction that intersects an extension direction of the pixel isolation portion, and
wherein the second portion includes an insulation layer adjacent to the plurality of pixel regions, a conductive layer on the insulation layer, and an inner layer at an inside of the conductive layer, the inner layer having a refractive index less than a refractive index of the conductive layer.

16. The image sensor of claim 15, wherein:
the plurality of pixel regions includes a first pixel region and a second pixel region adjacent to each other in one direction, and the pixel isolation portion extends in a direction intersecting the one direction between the first pixel region and the second pixel region,
the insulation layer includes first and second insulation portions respectively adjacent to the first and second pixel regions,
the first portion has an electrical connection structure between the first and second insulation portions at least partially defined by the conductive layer, and
the second portion has a total reflection structure at least partially defined by the conductive layer and the inner layer.

17. The image sensor of claim 15, wherein:
the inner layer includes an inner insulation layer including at least one of
an insulating material, or
inner surfaces at least partially defining a space portion having an internal space between opposing surfaces of the conductive layer in the intersection direction.

18. An image sensor, comprising:
a substrate including a plurality of pixel regions including a first pixel region and a second pixel region adjacent to each other;
a photoelectric converter at the substrate; and
a pixel isolation portion that separates the first pixel region and the second pixel region based on penetrating at least a part of the substrate between the first pixel region and the second pixel region,
wherein the pixel isolation portion includes
a first portion including first and second insulation portions respectively adjacent to the first and second pixel regions and a conductive layer that occupies a space defined between the first and second insulation portions in an intersection direction that intersects an extension direction of the pixel isolation portion, and
a second portion having a width greater than a width of the first portion and a stacking structure different from a stacking structure of the first portion to have an electrical insulation structure.

19. The image sensor of claim 18, wherein:
the second portion includes the first and second insulation portions, first and second conductive portions respectively on the first and second insulation portions, and an inner layer between the first and second conductive portions.

20. The image sensor of claim 19, wherein the inner layer includes an inner insulation layer including at least one of:
an insulating material, or
inner surfaces at least partially defining a space portion having an internal space between opposing surfaces of the conductive layer in the intersection direction.
